(19) United States
(12) Patent Application Publication
(10) Pub. No.: US 2026/0223452 A1
(43) Pub. Date: Jul. 30, 2026

(54) SEMICONDUCTOR DEVICE INCLUDING MULTI-STACK TRANSISTOR STRUCTURES HAVING DIFFERENT CHANNEL WIDTHS AND HEIGHTS

(71) Applicant: SAMSUNG ELECTRONICS CO., LTD., Suwon-si (KR)

(72) Inventors: Hyojong Shin, Mechanicville, NY (US); Edward Namkyu Cho, Slingerlands, NY (US); Jinyoung Lim, Schenectady, NY (US); Young Gook Park, Rensselaer, NY (US); Kang-ill Seo, Springfield, VA (US)

(73) Assignee: SAMSUNG ELECTRONICS CO., LTD., Suwon-si (KR)

(21) Appl. No.: 19/305,278

(22) Filed: Aug. 20, 2025

Related U.S. Application Data
(60) Provisional application No. 63/750,993, filed on Jan. 29, 2025.

(51) Int. Cl. H10D 84/85; H10D 84/01

(52) U.S. Cl. CPC H10D 84/856; H10D 84/0167; H10D 84/017; H10D 84/0188; H10D 84/851

(57) ABSTRACT

A semiconductor device includes a 1^{st} multi-stack transistor and a 2^{nd} multi-stack transistor arranged in a 1^{st} direction intersecting a 2^{nd} direction, wherein the 1^{st} multi-stack transistor includes a 1^{st} lower transistor and a 1^{st} upper transistor above the 1^{st} lower transistor in a 3^{rd} direction that intersects the 1^{st} direction and the 2^{nd} direction, wherein the 2^{nd} multi-stack transistor structure includes a 2^{nd} lower transistor and a 2^{nd} upper transistor above the 2^{nd} lower transistor in the 3^{rd} direction, and wherein the 1^{st} lower transistor and the 2^{nd} lower transistor have different numbers of effective lower channel layers.

### CROSS-REFERENCE TO THE RELATED APPLICATION

This application is based on and claims priority from U.S. Provisional Application No. 63/750,993 filed on Jan. 29, 2025 in the U.S. Patent and Trademark Office, the disclosure of which is incorporated herein in its entirety by reference.

### BACKGROUND

### 1. Field

Apparatuses and methods consistent with example embodiments of the disclosure relate to a semiconductor device in which a plurality of multi-stack transistors have different channel widths and different numbers of channel layers.

### 2. Description of the Related Art

Increasing demand for high-performance, high-density semiconductor devices has introduced a nanosheet transistor characterized by multiple nanosheet layers bridging source/drain regions formed at both ends thereof and a gate structure that wraps around or surround all four sides of the nanosheet layers. These nanosheet layers serve as a channel structure for current flow between the source/drain regions of the nanosheet transistor. Due to this structure, improved control of current flow through the nanosheet layers by the gate structure is enabled in addition to high-device density in a semiconductor device including the nanosheet transistor. The nanosheet transistor is also referred to as various different names such as gate-all-around transistor, multi-bridge channel field-effect transistor (MBCFET), nanobeam transistor, nanoribbon transistor, superimposed channel device, etc.

Further, a multi-stack transistor or a three-dimensional-stacked transistor has been introduced in a response to increased demand for an integrated circuit having a high device density and performance. The multi-stack transistor may include a lower transistor at a lower stack and an upper transistor at an upper stack, where each of the two transistors may be a field-effect transistor (FET) such as fin field-effect transistor (FinFET), nanosheet transistor, forksheet transistor, or any other type of FET.

As the nanosheet transistor and the multi-stack transistor including the nanosheet transistors are widely adopted to form a semiconductor device, more diverse transistor structures are required to implement an optimized semiconductor device in terms of performance, power consumption, device density, etc.

Information disclosed in this Background section has already been known to the inventors before achieving the embodiments of the present application or is technical information acquired in the process of achieving the embodiments. Therefore, it may contain information that does not form the prior art that is already known to the public.

### SUMMARY

The disclosure provides a semiconductor device including a plurality of multi-stack transistors which are arranged in a D1 direction on a same substrate, implemented in a semiconductor cell, and have different channel widths and different numbers of effective channel layers at a lower stack and/or an upper stack.

According to one or more embodiments, there is provided a semiconductor device which may include a 1^{st} multi-stack transistor and a 2^{nd} multi-stack transistor arranged in a 1st direction intersecting a 2^{nd} direction, wherein the 1^{st} multi-stack transistor includes a 1^{st} lower transistor and a 1^{st} upper transistor above the 1^{st} lower transistor in a 3^{rd} direction that intersects the 1^{st} direction and the 2^{nd} direction, wherein the 2^{nd} multi-stack transistor structure includes a 2^{nd} lower transistor and a 2^{nd} upper transistor above the 2^{nd} lower transistor in the 3^{rd} direction, and wherein the 1^{st} lower transistor and the 2^{nd} lower transistor have different numbers of effective lower channel layers.

According to one or more embodiments, there is provided a semiconductor device which may include a 1^{st} multi-stack transistor and a 2^{nd} multi-stack transistor arranged in a 1^{st} direction intersecting a 2^{nd} direction, wherein the 1^{st} multi-stack transistor includes a 1^{st} lower transistor and a 1^{st} upper transistor above the 1^{st} lower transistor in a 3^{rd} direction that intersects the 1^{st} direction and the 1^{nd} direction, wherein the 1^{nd} multi-stack transistor structure includes a 1^{nd} lower transistor and a 1^{nd} upper transistor above the 1^{nd} lower transistor in the 3^{rd} direction, and wherein the 1^{st} upper transistor and the 1^{nd} upper transistor have different numbers of effective upper channel layers.

According to one or more embodiments, there is provided a semiconductor device which may include a 1^{st} transistor including a plurality of channel layers and a 1^{st} source/drain regions at a lateral side of the plurality of channel layers, wherein at least one of the plurality of channel layers is not connected to the 1^{st} source/drain region.

According to one or more embodiments, there is provided a method of manufacturing a semiconductor device, the method including forming a 1^{st} multi-stack transistor and a 1^{nd} multi-stack transistor such that the 1^{st} multi-stack transistor and the 1^{nd} multi-stack transistor are arranged in a 1^{st} direction intersecting a 1^{nd} direction, the 1^{st} multi-stack transistor includes a 1^{st} lower transistor and a 1^{st} upper transistor above the 1^{st} lower transistor in a 3^{rd} direction that intersects the 1^{st} direction and the 2^{nd} direction, the 2^{nd} multi-stack transistor structure includes a 2^{nd} lower transistor and a 2^{nd} upper transistor above the 2^{nd} lower transistor in the 3^{rd} direction, and the 1^{st} lower transistor and the 2^{nd} lower transistor have different numbers of effective lower channel layers.

### BRIEF DESCRIPTION OF THE DRAWINGS

Example embodiments of the disclosure will be more clearly understood from the following detailed description taken in conjunction with the accompanying drawings in which:

FIGS. 1A-1E illustrate a semiconductor cell in which a semiconductor device including a plurality of multi-stack transistors is formed, the multi-stack transistors having different channel structures based on blocking structures and additional patterning of active patterns, according to one or more embodiments;

FIGS. 2A-2J illustrate cross-section views of intermediate semiconductor devices after respective steps of manufacturing a semiconductor device including a plurality of multi-stack transistors having different channel structures based on blocking structures and additional patterning of active patterns, according to one or more embodiments, according to one or more embodiments;

FIGS. 3A and 3B illustrate a flowchart of a method of manufacturing a semiconductor device including a plurality of multi-stack transistors having different channel structures based on blocking structures and additional patterning of active patterns, according to one or more embodiments;

FIGS. 4A-4E illustrate a semiconductor cell in which a semiconductor device including a plurality of multi-stack transistors is formed, the multi-stack transistors having different channel structures based on blocking structures and different structures of interlayer isolation layers, according to one or more other embodiments;

FIGS. 5A-5K illustrate cross-section views of intermediate semiconductor devices after respective steps of manufacturing a semiconductor device including a plurality of multi-stack transistors having different channel structures based on blocking structures and different structures of interlayer isolation layers, according to one or more embodiments;

FIGS. 6A and 6B illustrate a flowchart of a method of manufacturing a semiconductor device including a plurality of multi-stack transistors having different channel structures based on blocking structures and different structures of interlayer isolation layers, according to one or more embodiments; and

FIG. 7 is a schematic block diagram illustrating an electronic device including one or more semiconductor devices in which a plurality of multi-stack transistors are formed to have different channel widths, different numbers of channel layers, different source/drain region widths, and different source/drain region heights at a lower stack and an upper stack, according to one or more embodiments.

### DETAILED DESCRIPTION

All of the embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof. For example, channel layers, sacrificial layers, and isolation layers described herein may take a different type or form as long as the disclosure can be applied thereto.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, an element described as “below” or “beneath” another element would then be oriented “above” the other element. Thus, the term “below” can encompass both an orientation of above and below. The semiconductor device may be otherwise oriented (rotated 90 degrees or at other orientations) and the spatially relative descriptors used herein interpreted accordingly. As another example, when elements referred to as a “left” element and a “right” element may be a “right” element and a “left” element when a device or structure including these elements are differently oriented.

It will be understood that, although the terms “1^{st},” “2^{nd},” “3^{rd},” “4^{th},” “5^{th},” “6^{th},” etc. may be used herein to describe various elements, these elements should not be limited by these terms. These terms are only used to distinguish one element from another element. Thus, a 1^{st} element described in the descriptions of an embodiments could be termed a 2^{nd} element in the descriptions of another element or one or more claims, and vice versa without departing from the teachings of the disclosure.

As used herein, expressions such as “at least one of,” when preceding a list of elements, modify the entire list of elements and do not modify the individual elements of the list. For example, the expression, “at least one of a, b and c,” should be understood as including only a, only b, only c, both a and b, both a and c, both b and c, or all of a, b and c.

Herein, the terms of degree including “substantially” or “about” may be used. In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X. Still, when a term “same” is used to compare parameters of two or more elements, the term may cover “substantially same” parameters.

It will be understood that, when the term “contact” is used to describe two metal elements, for example, a metal line and a via structure, a barrier metal layer such including titanium (Ti), tantalum (Ta), titanium nitride (TiN), tantalum nitride (TaN), tungsten nitride (WN), nickel nitride (NiN), cobalt nitride (CoN), or platinum nitride (PtN), not being limited thereto, may be formed therebetween. Further, it will be understood that, when a metal contact structure is described as being formed on or contact a surface of a source/drain region, a silicide layer including cobalt silicide (CoSi₂), nickel silicide (NiSi₂), titanium silicide (TiSi₂), or tungsten silicide (WSi₂), not being limited thereto, may be formed therebetween.

It will be also understood that, even if a certain step or operation of manufacturing an apparatus or structure is described later than another step or operation, the step or operation may be performed later than the other step or operation unless the other step or operation is described as being performed after the step or operation.

Many embodiments are described herein with reference to cross-sectional views that are schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. Various regions illustrated in the figures are schematic in nature and their shapes are not intended to illustrate the actual shape of a region of a device and are not intended to limit the scope of the disclosure. Further, in the drawings, the sizes and relative sizes of layers and regions may be exaggerated for clarity.

For the sake of brevity, conventional elements, structures or layers of semiconductor devices including a nanosheet transistor and materials forming the same may or may not be described in detail herein. For example, a certain isolation layer or structure of a semiconductor device and materials forming the same may be omitted herein when this layer or structure is not related to the novel features of the embodiments. Also, descriptions of materials forming well-known structural elements of a semiconductor device may be omitted herein when those materials are not relevant to the novel features of the embodiments. Herein, the term “isolation” and “insulation” pertains to electrical insulation or separation between structures, layers, components or regions in a corresponding device or structure.

Performance and power of a fin field-effect transistor (FinFET) and a standard cell formed of FinFETs may be optimized by adjusting the number of fin structure forming a channel structure of each of the FinFETs. As technology advances to a nanosheet transistor, also referred to as a gate-all-around field-effect transistor (GAAFET), performance and power optimization may be achieved by adjusting channel widths of nanosheet layers forming a channel structure of the nanosheet transistor as the nanosheet transistor allows for more flexible width adjustment, and a standard cell with various channel widths offers advantages in implementing therein various different transistor structures satisfying diverse design requirements.

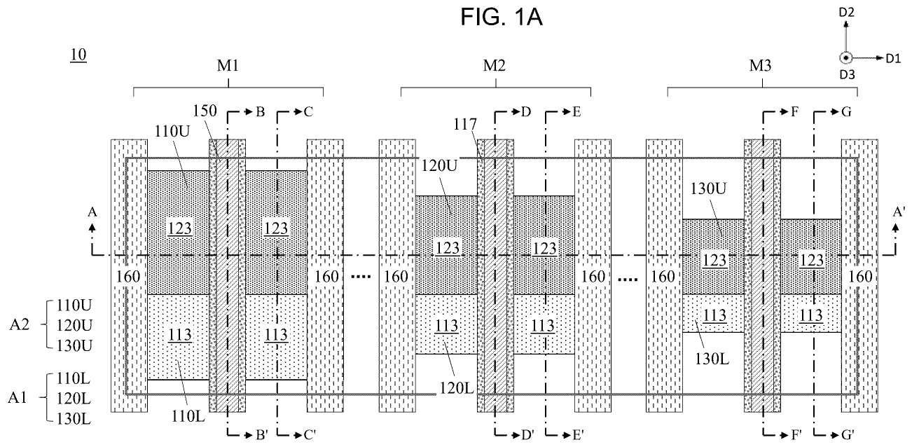

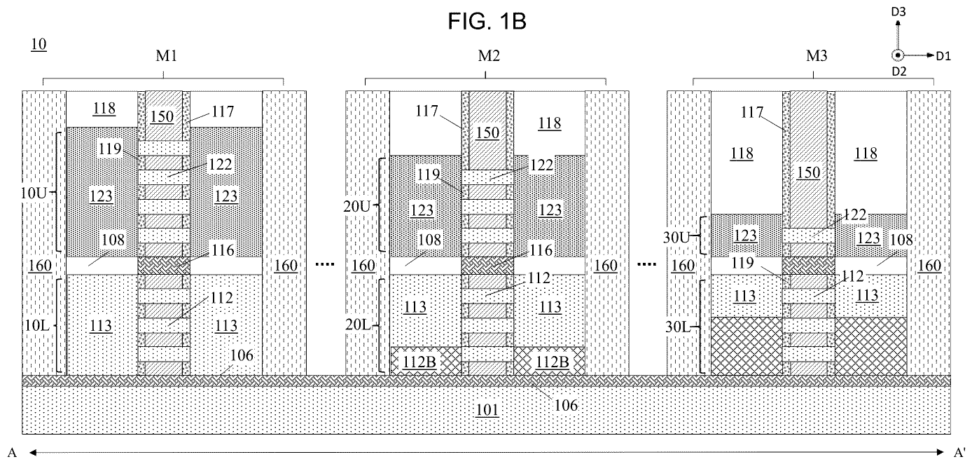

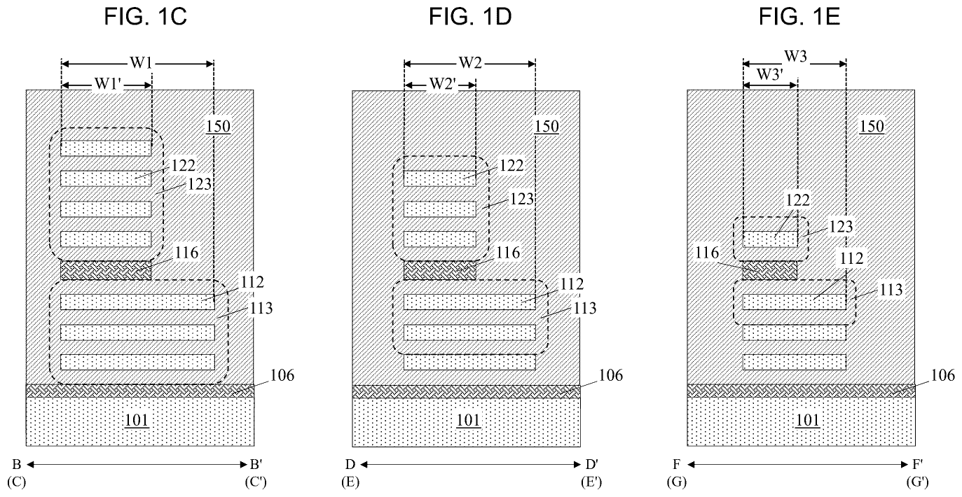

FIGS. 1A-1E illustrate a semiconductor cell in which a semiconductor device including a plurality of multi-stack transistors is formed, the multi-stack transistors having different channel structures based on blocking structures and additional patterning of active patterns, according to one or more embodiments.

FIG. 1A is a plan view of a semiconductor device 10 formed in a semiconductor cell, FIGS. 1B-1E are a cross-section views of the semiconductor device 10 taken along lines A-A′, B-B′, D-D′, E-E′ and F-F′, respectively, shown in FIG. 1A.

It is to be understood that FIGS. 1A-1E show only selected elements formed on a front side of the semiconductor device 10 such as front-end-of-line (FEOL) structures including channel structures, source/drain regions and gate structures, and thus, some structural elements such as back-end-of-line (BEOL) structures and middle-of-line (MOL) structures are not shown for brevity purposes. It is also to be understood that FIGS. 1C-1E show, in dashed lines, source/drain regions seen in cross-section views of the semiconductor device 10 taken along lines C-C′, E-E′ and G-G′, respectively, to assist understanding of structural and positional relationships between the source/drain regions, gate structures and single diffusion break (SDB) structures.

Referring to FIG. 1A, the semiconductor device 10 may include a 1^{st} multi-stack transistor M1, a 2^{nd} multi-stack transistor M2, and a 3^{rd} multi-stack transistor M3 formed on a lower active pattern A1 and an upper active pattern A2. The upper active pattern A2 may be stacked on the lower active pattern A1 formed on a substrate 101, both active patterns A1 and A2 extending in a D1 direction. The semiconductor device 10 may also include a plurality of gate structures 150 and SDB structures 160 arranged in the D1 direction and extending in a D2 direction, that intersects the D1 direction, across the active patterns A1 and A2.

The 1^{st} to 3^{rd} multi-stack transistors M1-M3 may each be bounded by the SDB structures 160 in the D1 direction. The SDB structures 160 may be formed of an isolation material and extend in the D2 direction. Between the 1^{st} to 3^{rd} multi-stack transistors M1-M3 may be formed one or more other multi-stack transistors or different types of active or passive devices.

The lower active pattern A1 may include a 1^{st} lower active pattern 110L, a 2^{nd} lower active pattern 120L and a 3^{rd} lower active pattern 130L connected in a row in the D1 direction and having respectively different D2 direction-widths. For example, the 1^{st} lower active pattern 110L may have a greater D2-direction width than the 1^{nd} lower active pattern 120L, and the 2^{nd} lower active pattern 120L may have a greater D2-direction width than the 3^{rd} lower active pattern 130L. Similarly, the upper active pattern A2 may include a 1^{st} upper active pattern 110U, a 2^{nd} upper active pattern 120U and a 3^{rd} upper active pattern 130U connected in a row in the D1 direction and having respectively different D2 direction-widths. For example, the 1^{st} upper active pattern 110U may have a greater D2-direction width than the 2^{nd} upper active pattern 120U, and the 2^{nd} upper active pattern 120U may have a greater D2-direction width than the 3^{rd} upper active pattern 130U. Hereinafter, the D2-direction width may be simply referred to as a “width.”

The 1^{st} to 3^{rd} upper active patterns 110U-130U may be stacked on the 1^{st} to 3^{rd} lower active patterns 110L-130L formed on a substrate 101, respectively, in a D3 direction that intersects the D1 direction and the D2 direction, and the 1^{st} to 3^{rd} upper active patterns 110U-130U may have the same D1-direction lengths as the 1^{st} to 3^{rd} lower active patterns 110L-130L, respectively. The 1^{st} to 3^{rd} upper active patterns 110U-130U may partially overlap the 1^{st} to 3^{rd} lower active patterns 110L-130L, respectively, in the D3 direction such that a side surface of each of the 1^{st} to 3^{rd} upper active patterns 110U-130U is aligned with or coplanar with a corresponding side surface each of the 1^{st} to 3^{rd} lower active patterns 110L-130U U-130U, while the other corresponding side surface of each of the 1^{st} to 3^{rd} upper active patterns 110U-130U is not aligned with or coplanar with the other side surface of each of the 1^{st} to 3^{rd} lower active patterns 110L-130L, in the D3 direction.

In addition to the width differences, the 1^{st} to 3^{rd} upper active patterns 110U-130U may have different heights in the D3 direction while the 1^{st} to 3^{rd} lower active patterns 110L-130L have a same height in the D3 direction. For example, the 1^{st} upper active pattern 110U may have a greater height than the 2^{nd} upper active pattern 120U, and the 1^{nd} upper active pattern 120U may have a greater height than the 3^{rd} upper active pattern 130U, in the D3 direction. Thus, as will be described later, the 1^{st} upper active pattern 110U may form a channel structure having a greater height than the 1^{nd} upper active pattern 120U, and the 1^{nd} upper active pattern 120U may form a channel structure having a greater height than the 3^{rd} upper active pattern 130U. In contrast, the 1^{st} to 3^{rd} lower active patterns 110L-130L may each form a channel structure having a same height. The height of a channel structure in the semiconductor device 10 may be defined or determined by a number of nanosheet layers as a channel structure arranged in the D3 direction as will be described later.

The substrate 101 may be a silicon (Si) substrate although it may be formed of other materials such as silicon germanium (SiGe), silicon carbide (SiC), not being limited thereto. The active patterns A1 and A2 may also be formed of Si, SiGe, SiC or so on, not being limited thereto.

Herein, the D1 direction refers to a channel-length direction, along which current flows between two source/drain regions through a channel structure. This may also be referred to as a cell-length direction. The D2 direction refers to a channel-width direction or a cell-height direction, and the D3 direction refers to a channel-thickness direction. The D1 and D2 directions may be termed horizontal directions, and the D3 direction a vertical direction.

Referring to FIGS. 1A and 1B, based on the lower active pattern A1 and the upper active pattern A2, the semiconductor device 10 may be formed of the 1^{st} multi-stack transistor M1 including a 1^{st} lower field-effect transistor (FET) 10L and a 1^{st} upper FET 10U, the 1^{nd} multi-stack transistor M2 including a 1^{nd} lower FET 20L and a 1^{nd} upper FET 20U, and the 3^{rd} multi-stack transistor M3 including a 3^{rd} lower FET 30L and a 3^{rd} upper FET 30U. Each of the lower FETs 10L-30L and the upper FETs 10U-30U may include at least one nanosheet layer as a channel structure thereof to form a nanosheet transistor. Herein, the nanosheet layer may be referred to as “a channel layer”.

Referring to FIGS. 1A-1E, the lower FETs 10L-30L may each include a lower channel structure formed of at least one lower channel layer 112 and the upper FETs 10U-30U may each include an upper channel structure formed of at least one upper channel layer 122. The lower channel structure and the upper channel structure in each of the multi-stack transistors M1-M3 may be isolated or separated by a middle dielectric isolation (MDI) layer 116. Each of the at least one lower channel layer 112 and the at least one upper channel layer 122 in each of the multi-stack transistors M1-M3 may be surrounded by the gate structure 150. Lower source/drain regions 113 epitaxially grown from the at least one lower channel layer 112 may be formed in each of the lower FETs 10L-30L, and upper source/drain regions 123 epitaxially grown from the at least one upper channel layer 122 may be formed in each of the upper FETs 10U-30U. A bottom diffusion isolation or bottom dielectric isolation (BDI) layer 106 may be formed between the gate structure 150 and the substrate 101 and may extend below the lower source/drain regions 113 to suppress current leakage from the gate structure 150 and the lower source/drain regions 113 to the substrate 101.

The lower source/drain regions 113 and the lower channel structure of the 1^{st} lower FET 10L may be formed based on the 1^{st} lower active pattern 110L, and the upper source/drain regions 123 and the upper channel structure of the 1^{st} upper FET 10U may be formed based on the 1^{st} upper active pattern 110U. The lower source/drain regions 113 and the lower channel structure of the 1^{nd} lower FET 20L may be formed based on the 1^{nd} lower active pattern 120L, and the upper source/drain regions 123 and the upper channel structure of the 2^{nd} upper FET 20U may be formed based on the 2^{nd} upper active pattern 120U. The lower source/drain regions 113 and the lower channel structure of the 3^{rd} lower FET 30L may be formed based on the 3^{rd} lower active pattern 130L, and the upper source/drain regions 123 and the upper channel structure of the 3^{rd} upper FET 30U may be formed based on the 3^{rd} upper active pattern 130U.

In each of the multi-stack transistors M1-M3, the source/drain regions 113 and 123 may be isolated from the gate structure 150 by gate spacers 117 and inner spacers 119 that are formed of the same or different insulation materials. The gate spacers 117 may be formed on side walls of an upper portion of the gate structure 150 above the uppermost upper channel layer 122. The inner spacers 119 may be formed between each of the source/drain regions 113 and 123 and the gate structure 150 in the D1 direction. A lower interlayer isolation layer 108 may be formed between the lower source/drain regions 113 and the upper source/drain regions 123, and an upper interlayer isolation layer 118 may be formed above the upper source/drain regions 123 in the D3 direction.

The channel layers 112 and 122 may be formed of a material including silicon (Si), the source/drain regions 113 and 123 may be formed of a material including silicon (Si) or silicon germanium (SiGe) and may be doped with impurities such as phosphorus (P), arsenic (As), antimony (Sb), etc. for n-type or boron (B), gallium (Ga), indium (In), etc. for p-type. The gate structures 150 may each include a gate dielectric layer, a work-function metal layer, and a gate-fill metal. The gate dielectric layer may include an interfacial layer formed on the channel layers 112 and 122 and including an oxide material such as silicon oxide (e.g., SiO₂). The gate dielectric layer may also include a high-k dielectric layer including a high-k material such as hafnium oxide (HfO₂), hafnium silicate (HfSiO₄), titanium oxide (TiO₂), zirconium oxide (ZrO₂), aluminum oxide (Al₂O₃), lanthanum oxide (La₂O₃), yttrium oxide (Y₂O₃), etc. The work-function metal layer may be formed of titanium (Ti), tantalum (Ta) or their compound such as TiN, TiAl, TiAlN, TaN, TiC, TaC, TiAlC, TaCN, TaSiN, and/or an alloy thereof, not being limited thereto. The gate-fill metal may be formed of copper (Cu), Al, tungsten (W), molybdenum (Mo), ruthenium (Ru), cobalt (Co) or their alloy, not being limited thereto.

The gate spacers 117 may be formed of an insulation material including silicon nitride (Si₃N₄), silicon carbon nitride (SiCN), silicon oxycarbide (SiOC) or silicon oxynitride (SiON), not being limited thereto. The inner spacers 119 may be formed of an insulation material including silicon nitride (Si₃N₄), silicon carbon nitride (SiCN), silicon oxynitride (SiON), silicon oxycarbide (SiOC), silicon boron carbonitride (SiBCN), or silicon oxy carbonitride (SiOCN), not being limited thereto. The interlayer isolation layers 108 and 118 may be formed of silicon oxide (SiO₂), not being limited thereto. The BDI layer 106 and the MDI layer 116 may be formed of SiBCN, SiCN, SiOC, SiOCN, Si3N4, or the like, not being limited thereto. The SDB structures 160 may be formed of silicon oxide (e.g., SiO₂), silicon nitride (e.g., Si₃N₄), tonen silazene (TOSZ), or the like, not being limited thereto.

Due to the difference in widths between the lower active pattern A1 and the upper active pattern A2, the semiconductor device 10 may have different channel widths between the lower FETs 10L-30L and the respective upper FETs 10U-30U, between the lower FETs 10L-30L, and between the upper FETs 10U-30U. Further, the semiconductor device 10 may have different numbers of channel layers between the lower FETs 10L-30L and the respective upper FETs 10U-30U, and between the upper FETs 10U-30U. Herein, the channel width may refer to a width in the D2 direction. However, the semiconductor device 10 may have the same number of lower channel layers 112 between the lower FETs 10L-30U although the number of effective lower channel layers 112 may be different therebetween as will be described later.

Regarding the channel-width difference in the semiconductor device 10, while each of the 1^{st} to 3^{rd} multi-stack transistors M1-M3 has a lower channel structure formed of at least one lower channel layer 112 for the lower FET and an upper channel structure formed of at least one upper channel layer 122 for the upper FET, the at least one upper channel layer 122 may have a smaller width than the at least one lower channel layer 112.

For example, in the 1^{st} multi-stack transistor M1, the at least one upper channel layer 122 of the 1^{st} upper FET 10U may have a width W1′, which is smaller than a width W1 of the at least one lower channel layer 112 of the 1^{st} lower FET 10L. In the 1^{nd} multi-stack transistor M2, the at least one upper channel layer 122 of the 1^{nd} upper FET 20U may have a width W2′, which is smaller than a width W2 of the at least one lower channel layer 112 of the 1^{nd} lower FET 20L. In the 1^{st} multi-stack transistor M3, the at least one upper channel layer 122 of the 3^{rd} upper FET 30U may have a width W3′, which is smaller than a width W3 of the at least one lower channel layer 112 of the 3^{rd} lower FET 30L.

Further, as the 1^{st} lower active pattern 110L and the 1^{st} upper active pattern 110U have greater widths than the 1^{nd} lower active pattern 120L and the 1^{nd} upper active pattern 120U, respectively, which have greater widths than the 3^{rd} lower active pattern 130L and the 3^{rd} upper active pattern 130U, respectively, the width W1 may be greater than the width W2 which is greater than the width W3, and the width W1′ may be greater than the width W2′ which is greater than the width W3′.

According to the channel width differences described above, widths of source/drain regions epitaxially grown from the channel structures of the semiconductor device 10 may also differ from each other. For example, in each of the 1^{st} to 3^{rd} multi-stack transistors M1-M3, the upper source/drain regions 123 epitaxially grown from the at least one upper channel layer 122 may have greater widths than the lower source/drain regions 113 epitaxially grown from the at least one lower channel layer 112, respectively. Further, the lower source/drain region 113 of the 1^{st} lower FET 10L may have a greater width than the lower source/drain region 113 of the 1^{nd} lower FET 20L, which has a greater width than the lower source/drain region 113 of the 3^{rd} lower FET 30L, and the upper source/drain region 123 of the 1^{st} upper FET 10U may have a greater width than the upper source/drain region 123 of the 2^{nd} upper FET 20U, which has a greater width than the upper source/drain region 123 of the 3^{rd} upper FET 30U.

Regarding the difference in the numbers of channel layers in the semiconductor device 10, each of the 1^{st} to 3^{rd} multi-stack transistors M1-M3 may have the same number or different numbers of channel layers between the lower FETs 10L-30L and the upper FETs 10u-30U. Or, each of the 1^{st} to 3^{rd} multi-stack transistors M1-M3 may have the same channel-structure height or different channel-structure heights between the lower FETs 10L-30L and the upper FETs 10U-30U.

For example, the 1^{st} to 3^{rd} lower FETs 10L-30L may each have three lower channel layers 112 while the 1^{st} to 3^{rd} upper FETs 10U-30U may have four upper channel layers 122, three upper channel layers 122, and one upper channel layer 122, respectively. Thus, the 1^{st} lower FET 10L and the 1^{st} upper FET 10U may have different numbers of channel layers, respectively, and the 3^{rd} lower FET 30L and the 3^{rd} upper FET 30U may also have different numbers of channel layers, respectively. In contrast, the 1^{nd} lower FET 20L and the 1^{nd} upper FET 20U may have the same number of channel layers. Here, the channel layers 112 and 122 may each have a same thickness or same height in the D3 direction.

However, in the 1^{nd} lower FET 20L, the lowermost lower channel layer 112 among the three lower channel layers 112 may be deactivated or disabled by a blocking structure 112B formed at each lateral side of the lowermost channel layer 112 in the D1 direction while the other two lower channel layers 112 may be connected to the lower source/drain regions 113. In effect, the 1^{nd} multi-stack transistor M2 may have only two effective lower channel layers 112 and three effective upper channel layers 122. The blocking structure 112B may be formed earlier than the lower source/drain regions 113 in a manufacturing process of the semiconductor device 10, and thus, the epitaxial growth of the lower source/drain regions 113 from the lowermost lower channel layers 112 may be prevented by the blocking structure 112B. Accordingly, the lower source/drain regions 113 in the 1^{nd} lower FET 20L may have a smaller height in the D3 direction than the lower source/drain regions 113 in the 1^{st} lower FET 10L. The blocking structure 112B may be formed of an isolation material such as Si₃N₄, SiBCN, SiCN, SiOC, SiOCN, or the like, not being limited thereto.

Similarly, in the 3^{rd} lower FET 30L, the two lowermost lower channel layers 112 among the three lower channel layers 112 may be deactivated or disabled by a blocking structure 112B formed at each lateral side of the two lowermost lower channel layers 112 in the D1 direction while the other lower channel layer 112 may be connected to the lower source/drain regions 113. In effect, the 3^{rd} multi-stack transistor M3 may have only one effective lower channel layer 112 and one effective upper channel layer 122. This blocking structure 112B may also be formed earlier than the lower source/drain regions 113 in the 3^{rd} lower FET 30L in the manufacturing process of the semiconductor device 10, and thus, the epitaxial growth of the lower source/drain regions 113 from the two lowermost lower channel layers 112 may be prevented by the blocking structure 112B. Accordingly, the lower source/drain regions 113 in the 3^{rd} lower FET 30L may have a smaller height than the lower source/drain regions 113 in the 1^{nd} lower FET 20L in the D3 direction.

As no blocking structure 112B is formed in the 1^{st} lower FET 10L, all three lower channel layers 112 therein may be effective channel layers. All four upper channel layers 122 of the 1^{st} upper FET 10U may also be effective channel layers.

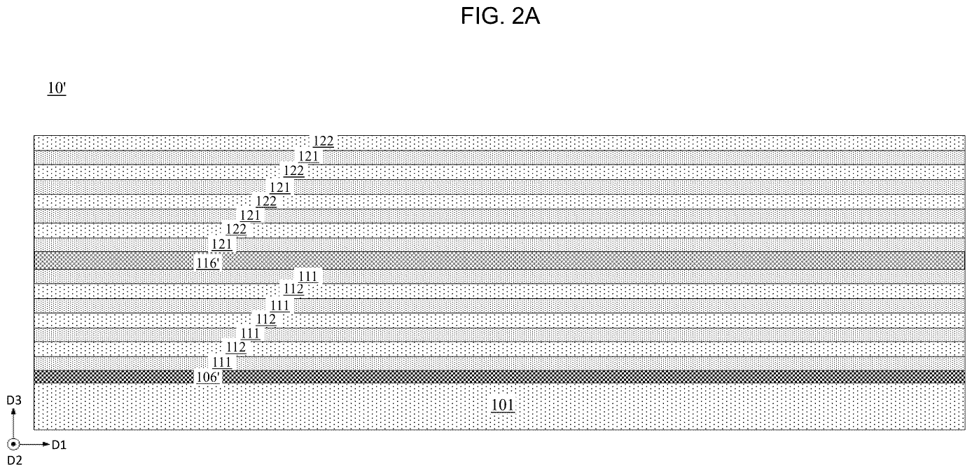

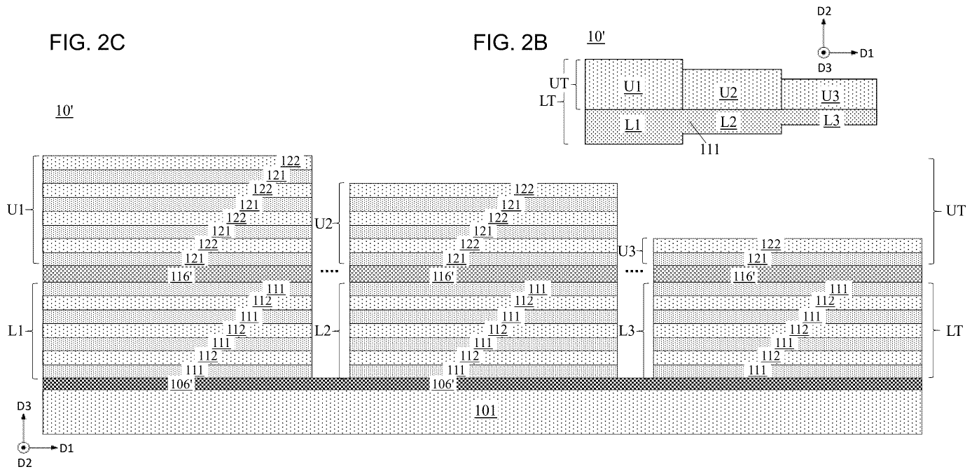

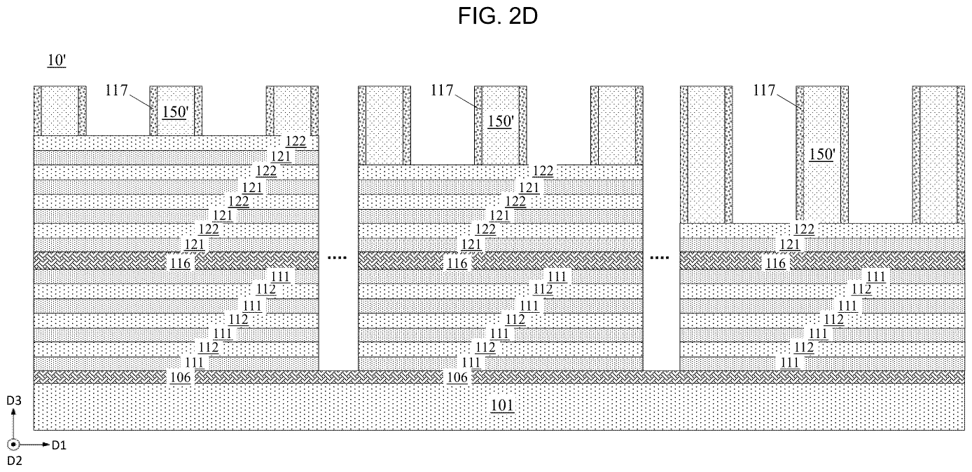

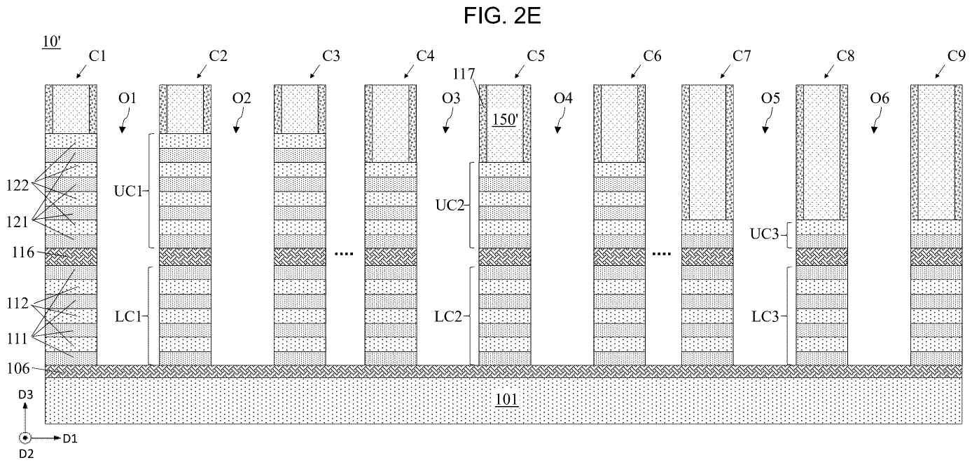

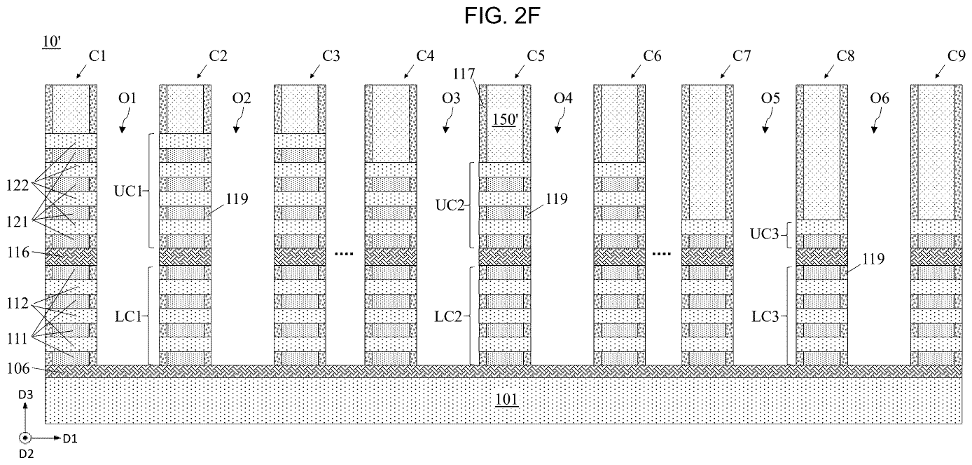

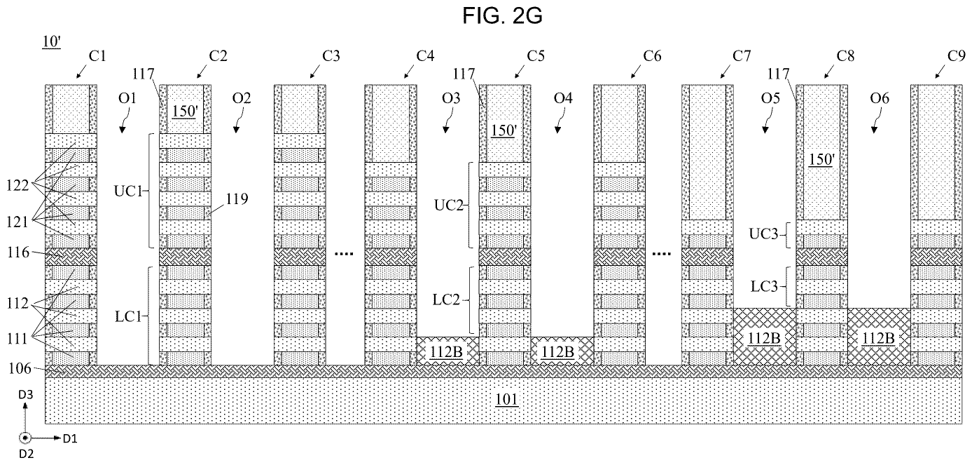

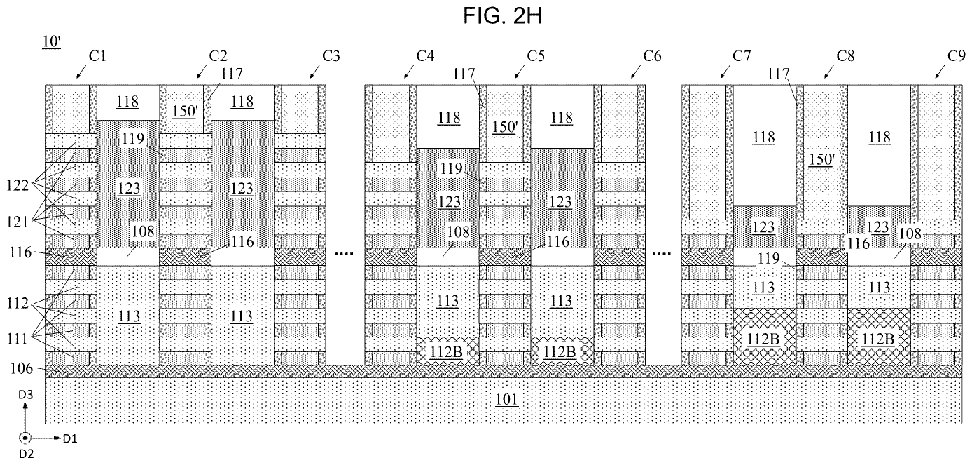

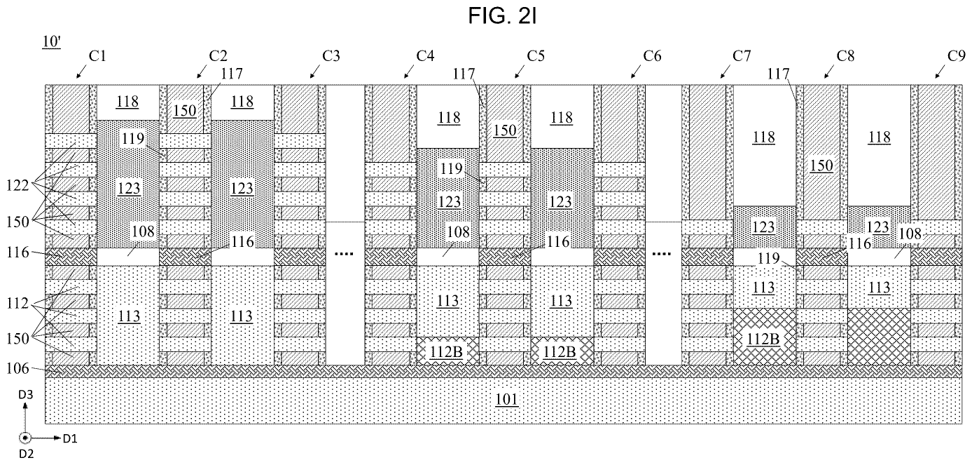

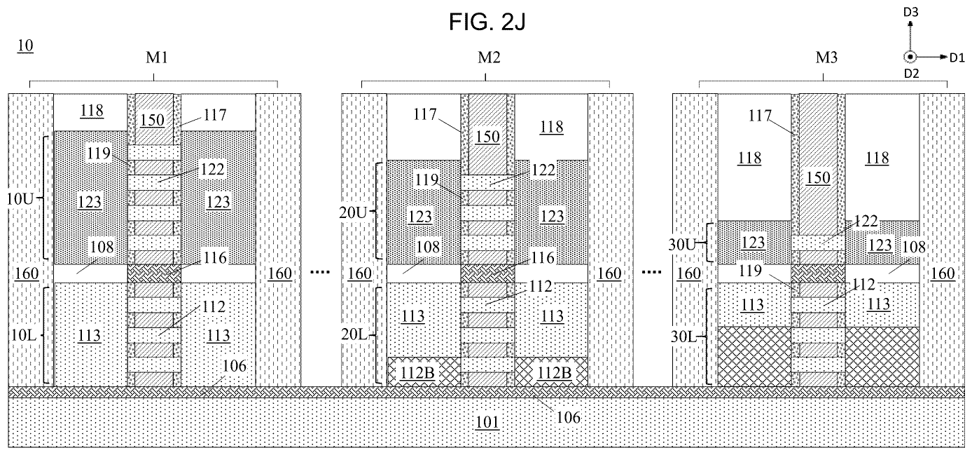

In contrast to the lower channel layers 112 of the 1^{st} to 3^{rd} lower FETS 10L-30L, the 1^{st} to 3^{rd} upper FETs 10U-30U may have different numbers of upper channel layers 122 or different channel-structure heights. As will be described later in reference to FIGS. 2A-2J, the 1^{nd} upper active pattern 120U may be formed to have a smaller height than the 1^{st} upper active pattern 110U, and the 3^{rd} upper active pattern 130U may be formed to have a smaller height than the 1^{nd} upper active pattern 120U, in the D3 direction. Thus, the 1^{nd} upper FET 20U may have a smaller number of the upper channel layers 122 than the 1^{st} upper FET 10U, and the 3^{rd} upper FET 30U may have a smaller number of the upper channel layers 122 than the 1^{nd} upper FET 20U. For example, the 1^{st} to 3^{rd} upper FETs 10U-30U may have four upper channel layers 122, three upper channel layers 122, and one upper channel layer 122, respectively.

As described above, the semiconductor device 10 may be structured to have a plurality of multi-stack transistors M1-M3, for example, multi-stack nanosheet transistors arranged in the D1 direction and having different channel widths in the D2 direction and different numbers of channel layers 112 and 122 or channel-structure heights in the D3 direction. As the semiconductor device 10 is structured in the above manner, the semiconductor device 10 may implement a plurality of different multi-stack transistors having different performances and device densities for different uses.

In the meantime, the semiconductor cell in which the semiconductor device 10 is formed as shown in FIG. 1A may be defined by a cell boundary BR formed of left and right boundaries and upper and lower boundaries. On the left and right boundaries may be formed the SDB structures 160, respectively, and, on the upper and lower boundaries may be formed power rails connecting the structural elements of the semiconductor device 10 to a positive voltage source and a negative voltage source, respectively. Thus, the semiconductor device including the 1^{st} to 3^{rd} multi-stack transistors T1-T3 may be formed in a single-height semiconductor cell defined by the upper and lower boundaries.

Herebelow, a method of manufacturing the semiconductor device 10 of FIGS. 1A-1E is provided.

FIGS. 2A-2J illustrate cross-section views of intermediate semiconductor devices after respective steps of manufacturing a semiconductor device including a plurality of multi-stack transistors having different channel structures based on blocking structures and additional patterning of active patterns, according to one or more embodiments, according to one or more embodiments.

The semiconductor device manufactured through the steps described in reference to FIGS. 2A-2J may be the same as or correspond to the semiconductor device 10 shown in FIGS. 1A-1E. Thus, materials, functions, and structural characteristics of the intermediate semiconductor devices shown in FIGS. 2A-2J may be the same as or similar to those of the semiconductor device 10 of FIGS. 1A-1E, and thus, duplicate descriptions may be omitted herein while the same reference characters or numerals used in reference to FIGS. 1A-1E may be used herebelow. It is also to be understood here that the cross-section views of FIGS. 2A-2J correspond to the cross-section view of the semiconductor device 10 in the D1 direction as shown in FIG. 1B.

Referring to FIG. 2A, an intermediate semiconductor device 10′ may be formed by epitaxially growing a plurality of semiconductor layers one by one from a substrate 101.

The intermediate semiconductor device 10′, which is a semiconductor stack, may be formed through a method such as ultra-high vacuum chemical deposition, not being limited thereto, to grow, from the substrate 101, a plurality of semiconductor layers including a plurality of sacrificial layers and a plurality of channel layers to be formed as channel structures of a semiconductor device in a later step.

The intermediate semiconductor device 10′ may include a bottom sacrificial layer 106′ on the substrate 101, a lower stack formed of lower sacrificial layers 111 and lower channel layers 112 vertically stacked in an alternating manner, a middle sacrificial layer 116′, and an upper stack formed of upper sacrificial layers 121 and upper channel layers 122 vertically stacked in an alternating manner. Here, the growth of the semiconductor layers on the substrate 101 may be performed such that each of the channel layers 112 and 122 may have the same height or thickness in the D3 direction.

While the substrate 101 and the channel layers 112 and 122 may be formed of silicon (Si), the sacrificial layers 106′, 116′, 111 and 121 may be formed of silicon germanium (SiGe) with respective Ge concentrations therein. The bottom sacrificial layer 106′ and the middle sacrificial layer 116′ may have a higher Ge concentration than the lower sacrificial layers 111 and the upper sacrificial layers 121 to provide etch selectivity. For example, the bottom sacrificial layer 106′ and the middle sacrificial layer 116′ may have a Ge concentration of 40-45%, and the lower sacrificial layers 111 and the upper sacrificial layers 121 may have a Ge concentration of 25-30%.

Referring to FIGS. 2B and 2C, the intermediate semiconductor device 10′ obtained in the previous step may be patterned to form a plurality of semiconductor stacks.

By the patterning operation in this step, the intermediate semiconductor device 10′ shown in FIG. 2A may be patterned to form a lower stack LT including 1^{st} to 3^{rd} lower stacks L1-L3 and an upper stack UT including 1^{st} to 3^{rd} upper stacks U 1-U3 respectively formed on the 1^{st} to 3^{rd} lower stacks L1-L3.

The intermediate semiconductor device 10′ may be patterned in the D1 direction and the D2 direction as shown in FIG. 2B such that the 2^{nd} lower stack L2 and the 2^{nd} upper stack U2 have smaller widths than the 1^{st} lower stack L1 and the 1^{st} upper stack U1, respectively, and the 3^{rd} lower stack L3 and the 3^{rd} upper stack U3 have smaller widths than the 1^{nd} lower stack L2 and the 1^{nd} upper stack U2, respectively.

The intermediate semiconductor device 10′ may also be patterned in the D3 direction as shown in FIG. 2C such that a top surface of the uppermost lower sacrificial layer 111, which is a top surface of the lower stack LT formed of the 1^{st} to 3^{rd} lower stacks L1-L3, is partially exposed. Thus, the 1^{st} to 3^{rd} upper stacks U1-U3 may have smaller widths than the 1^{st} to 3^{rd} lower stacks L1-L3, respectively. In addition, the D3-direction patterning is performed such that the 1^{nd} upper stack U2 has a smaller height than the 1^{st} upper stack U1 and the 3^{rd} upper stack U3 has a smaller height than the 1^{nd} upper stack U2, while the 1^{st} to 3^{rd} lower stacks L1-L3 have a same height which is smaller than the heights of the 1^{st} to 3^{rd} upper stacks U1-U3.

The foregoing D3-direction patterning may be performed by partially removing respective portions of the upper channel layers 122, the upper sacrificial layers 121 and the middle sacrificial layer 116′ to expose a portion of the uppermost lower sacrificial layer 111 forming top surfaces of the 1^{st} to 3^{rd} lower stacks L1-L3 at a same level as shown in FIG. 2B. Further, the remaining portions of the upper channel layers 122 and the upper sacrificial layers 121 may be patterned such that the 1^{nd} upper stack U2 has a smaller height than the 1^{st} upper stack U1 by heights of one upper channel layer 122 and one upper sacrificial layer 121 and the 3^{rd} upper stack U3 has a smaller height than the 1^{nd} upper stack U2 by two upper channel layers 122 and two upper sacrificial layers 121 while the 1^{st} to 3^{rd} lower stacks L1-L3 maintain a same height in the D3 direction.

The patterning operation in this step may be performed through, for example, hard masking, lithography and dry etching.

Referring to FIG. 2D, the bottom sacrificial layer 106′ and the middle sacrificial layer 116′ may be removed and replaced by a BDI layer 106 and an MDI layer 116, respectively, and a plurality of dummy gate structures 150′ and gate spacers 117 may be formed at a predetermined interval on the intermediate semiconductor device 10′.

The removal of the bottom sacrificial layer 106′ and the middle sacrificial layer 116′ may be performed through, for example, dry etching or wet etching using an etchant such as an ammonia-peroxide mixture etching the SiGe layers having a high Ge concentration while the channel layers 112 and 122 of silicon (Si) and sacrificial layers 111 and 121 of SiGe with a low Ge concentration are not attacked or minimally attacked by the etchant. Subsequently, an isolation material including SiBCN, SiCN, SiOC, SiOCN, Si₃N₄, or the like may be formed in spaces provided by the removal of the bottom sacrificial layer 106′ and the middle sacrificial layer 116′ through, for example, atomic layer deposition (ALD), not being limited thereto to form the BDI layer 106 and the MDI layer 116, respectively.

The dummy gate structures 150′ may be formed on a top surface of the intermediate semiconductor device 10′ at a predetermined interval or contact-poly-pitch (CPP) along the D1 direction at positions below which respective channel stacks are to be formed in a next step (FIG. 2E). The dummy gate structures 150′ may be formed by depositing polysilicon (p-Si) or amorphous silicon (a-Si) on the top surface of the intermediate semiconductor device 10′ through, for example, physical vapor deposition (PVD), chemical vapor deposition (CVD), plasma enhanced chemical vapor deposition (PECVD), or a combination thereof, to form an initial dummy gate structure, and applying masking, lithography and dry etching on the initial dummy gate structure.

The dummy gate structures 150′ may be formed to protect structural elements formed therebelow from various operations such as deposition and etching performed to form surrounding structures in subsequent manufacturing steps. The dummy gate structures 150′ may also serve to define dimensions of channel layers of each channel stack to be formed from the intermediate semiconductor device 10′.

Subsequent to the formation of the dummy gate structures 150′, the gate spacers 117 may be formed on side walls of each dummy gate structure 150′ to isolate the dummy gate structure 150′ and a gate structure, that will replace the dummy gate structure 150′ in a later step (FIG. 2I), from surrounding structural elements including source/drain regions also to be formed in a later step (FIG. 2H). The formation of the gate spacers 117 may be performed through, for example, CVD, PECVD, etc. and dry etching, not being limited thereto. The gate spacers 117 may be formed of Si3N4, SiCN, SiOC or SiON, not being limited thereto.

Referring to FIG. 2E, the intermediate semiconductor device 10′ may be patterned based on the dummy gate structure 150′ and the gate spacers 117 to form a plurality of channel stacks including 1^{st} to 7^{th} channel stacks C1-C9 with respective openings O1-O6 therebetween on the substrate 101.

A hard mask pattern may be formed on a top surface of each of the dummy gate structures 150′ for the patterning operation in this step which may be performed through, for example, dry etching such as reactive ion etching (RIE).

By the patterning operation in this step, the 1^{st} to 7^{th} channel stacks C1-C9 may be formed on the substrate 101 with the respective openings O1-O6 therebetween, and a top surface of the BDI layer 106 on the substrate 101 may be exposed through these openings. Each of the channel stacks C1-C9 may include a lower channel stack formed on the BDI layer 106 and an upper channel stack formed on the lower channel stack with the MDI layer 116 therebetween.

For example, each of the 1^{st} to 3^{rd} channel stacks C1-C3 may include a lower channel stack LC1 formed of four lower sacrificial layers 111 and three lower channel layers 112 and an upper channel stack UC1 formed of four upper sacrificial layers 121 and four upper channel layers 122. Each of the 4^{th} to 6^{th} channel stacks C4-C6 may include a lower channel stack LC2 formed of four lower sacrificial layers 111 and three lower channel layers 112 and an upper channel stack UC2 formed of three upper sacrificial layers 121 and three upper channel layers 122. Further, each of the 7^{th} to 9^{th} channel stacks C7-C9 may include a lower channel stack LC3 formed of four lower sacrificial layers 111 and three lower channel layers 112 and an upper channel stack UC3 formed of a single sacrificial layer 121 and a single upper channel layer 122.

Referring to FIG. 2F, side portions of each of the sacrificial layers 111 and 121 in each of the channel stacks C1-C9 may be removed, and inner spacers 119 may be formed in spaces provided by the removal of the side portions of each of the sacrificial layers 111 and 121.

To form the spaces where the inner spacers 119 are to be formed in each of the channel stacks C1-C9, a selective etching operation may be performed on side surfaces of each of the channel stacks C1-C9 to pull back or etch away portions of the sacrificial layers 111 and 121 underlying below the gate spacer 117 in each of the channel stacks C1-C97. For example, isotropic etching may be applied using an etchant such as a hydrogen chloride gas which etches an SiGe or Ge component in the sacrificial layers 111 and 121 without attacking or with only minimally attacking an Si component in the channel layers 112 and 122. As the selective etching may attack only the SiGe or Ge component, at least a portion of each of the sacrificial layers 111 and 121 underlying below the gate spacers 117 may be removed, and thus, respective cavities or grooves may be formed at sides of the sacrificial layers 111 and 121.

Subsequently, the cavities or grooves formed in each of the channel stacks C1-C9 may be filled in with an isolation material to form the inner spacers 119 therein through, for example, ALD, CVD, PECVD or plasma enhanced atomic layer deposition (PEALD), etc., followed by isotropic wet chemical etching or dry etching to remove the isolation material not vertically below the gate spacers 117. The inner spacers 119 are to isolate a gate structure, that will replace the sacrificial layers 111 and 121 in a later step (FIG. 2I), from source/drain regions to be formed also in a later step (FIG. 2H).

Referring to FIG. 2G, blocking structures 112B may be formed to isolate or block selected channel layers in the intermediate semiconductor device 10′.

The blocking structure 112B may be formed in the openings O3 and O4 at lateral sides of the 5^{th} channel structure C5 and the openings O5 and O6 at lateral sides of the 8^{th} channel stack C8 on the top surface of the BDI layer 106. In the opening O3 and O4, the blocking structure 112B may be formed to block and disable the lowermost lower channel layer 112 of each of the 4^{th} to 6^{th} channel stacks C4 -C4 toward the openings O3 and O4, and, in the openings O5 and O6, the blocking structure 112B may be formed to block and disable two lowermost lower channel layers 112 of each of the 7^{th} to 9^{th} channel stacks C7-C9 toward the openings O5 and O6. Each of the 5^{th} channel stack C5 and the 8^{th} channel stack C8 as well as the 1^{nd} channel stack C2 is to form a channel structure of a multi-stack transistor in a later step (FIG. 2J).

The blocking structure 112B in the openings O3 and O4 may be formed such that a top surface thereof is at a level of or above a top surface of the lowermost lower channel layer 112 of each of the 4^{th} to 6^{th} channel stacks C4-C4, and the blocking structure 112B in the openings O5 and O6 may be formed such that a top surface thereof is at a level of or above a top surface of the 1^{nd} lowermost lower channel layer 112 of each of the 7^{th} to 9^{th} channel stacks C7-C9. Thus, a multi-stack transistor to include a channel structure to be formed from the 4^{th} to 6^{th} channel stacks C4-C4 may have only two effective lower channel layers 112 in the 5^{th} channel stack C5, and a multi-stack transistor to include a channel structure to be formed from the 7^{th} to 9^{th} channel stacks C7-C9 may have only one effective lower channel layer 112 in the 8^{th} channel stack C8.

The formation of the blocking structure 112B may be performed through, for example, depositing an isolation material such as Si₃N₄, SiBCN, SiCN, SiOC, SiOCN, or the like, not being limited thereto, in the openings O3-O6 as described above.

Referring to FIG. 2H, lower source/drain regions 113 and upper source/drain regions 123 may be formed in the openings O1-O6 based on the channel layers 112 and 122, respectively.

The lower source/drain regions 113 may be epitaxially grown from the lower channel layers 112 exposed to the openings O1-O6 through, for example, molecular beam epitaxy (MBE), vapor-phase epitaxy (VPE), etc., not being limited thereto. Due to the blocking structures 112B blocking and disabling the lowermost lower channel layers 112 in the openings O3 and O4, the lower source/drain regions 113 grown therein from the remaining two lower channel layers 112 may have a smaller height than the lower source/drain regions 113 grown therein from all three lower channel layers 112. Further, due to the blocking structures 112B blocking and disabling two lowermost lower channel layers 112 in the openings O5 and O6, the lower source/drain regions 113 grown therein from one remaining lower channel layer 112 may have a smaller height than the lower source/drain regions grown from two lower channel layers 112 in the openings O3 and O4.

The lower source/drain regions 113 may be formed of Si or SiGe and may be doped in-situ with impurities such as phosphorus (P), arsenic (As), antimony (Sb), etc. for n-type or boron (B), gallium (Ga), indium (In), etc. for p-type.

The upper source/drain regions 123 may be epitaxially grown from the upper channel layers 122 exposed to the openings O1-O6 through, for example, MBE, VPE, etc., not being limited thereto. Due to the difference of the number of the upper channel layers 122 between the 1^{st} to 3^{rd} upper channel stacks UC1-UC3 caused by the D3-direction patterning described in reference to FIGS. 2B and 2C, the upper source/drain regions 123 formed in the openings O1-O6 may have respectively different heights. For example, the upper source/drain regions 123 grown from three upper channel layers 122 in the openings O3 and O4 may have a smaller height than the upper source/drain regions 123 grown from four upper channel layers 122 in the openings O1 and O2. Further, the upper source/drain regions 123 grown from a single upper channel layer 122 in the openings O5 and O6 may have a smaller height than the upper source/drain regions 123 grown from three upper channel layers 122 in the openings O3 and O4.

The upper source/drain regions 123 may also be formed of Si or SiGe and may be doped in-situ with impurities such as P, As, Sb, etc. for n-type or B, Ga, In, etc. for p-type.

In the meantime, due to the above-described channel-width differences and channel-number differences, widths and heights of the source/drain regions 113 and 123 grown from the respective channel layers may also differ in a plurality of multi-stack transistors to be formed therefrom.

A lower interlayer isolation layer 108 may be formed between the lower source/drain regions 113 and the upper source/drain regions 123, and an upper interlayer isolation layer 118 may be formed above the upper source/drain regions 123 to isolate the source/drain regions 113 and 123 from each other or from other circuit elements, in the openings O1-O6. The interlayer isolation layers 108 and 118 may be formed of a low-k dielectric material such as silicon oxide (e.g., SiO₂).

Referring to FIG. 2I, the dummy gate structures 150′ and the sacrificial layers 111 and 121 may be removed and replaced by respective gate structures 150.

The dummy gate structures 150′ and the sacrificial layers 111 and 121 may be removed from the channel structures C1-C7 through, for example, dry etching, wet etching, or a combination thereof, not being limited thereto, using an etchant, for example, as a mixture of nitric acid (HNO3) and hydrofluoric acid (HF), not being limited thereto. Subsequently, spaces provided by the removal of the dummy gate structures 150′ and the sacrificial layers 111 and 121 may be filled in with the gate structures 150.

The gate structures 150 may each include a gate dielectric layer, a work-function metal layer, and a gate-fill metal. The gate dielectric layer may also include a high-k dielectric layer including a high-k material such as hafnium oxide (HfO₂), hafnium silicate (HfSiO₄), titanium oxide (TiO₃), zirconium oxide (ZrO₂), aluminum oxide (Al₂O₃), lanthanum oxide (La₂O₃), yttrium oxide (Y₂O₃), etc. The work-function metal layer may be formed of titanium (Ti), tantalum (Ta) or their alloy such as TiN, TiAl, TiAlN, TaN, TiC, TaC, TiAlC, TaCN, and TaSiN, not being limited thereto. The gate-fill metal may be formed of copper (Cu), Al, tungsten (W), molybdenum (Mo), ruthenium (Ru), cobalt (Co) or their alloy, not being limited thereto.

The formation of the gate structure 150 may be performed through, for example, CVD, PVD, PECVD, ALD, PEALD, etc. or a combination thereof, not being limited thereto.

Referring to FIG. 2J, the 1^{st}, 3^{rd}, 4^{th}, 6^{th}, 7^{th} and 9^{th} channel stacks C1, C3, C4, C6, C7 and C9 may be removed and replaced by respective SDB structures 160 to form a semiconductor device 10 including multi-stack transistors M1-M3 isolated by the SDB structures 160.

Masking, lithography and dry etching may be performed to remove the 1^{st}, 3^{rd}, 4^{th}, 6^{th}, 7^{th} and 9^{th} channel stacks C1, C3, C4, C6, C7 and C9 and respective portions of the substrate 101 and the BDI layer 106 thereon, and spaces provided by this removal operation may be filled in with an isolation material such as silicon oxide (e.g., SiO₂), silicon nitride (e.g., Si₃N₄), tonen silazene (TOSZ), or the like, not being limited thereto, to form the SDB structures 160.

Through the above embodiments described in reference to FIGS. 2A-2J, a semiconductor device including a plurality of multi-stack transistors having different channel widths, different numbers of channel layers, different source/drain region widths, and different source/drain region heights at a lower stack and an upper stack may be formed on a same substrate and implemented in a semiconductor cell having a predetermined cell height.

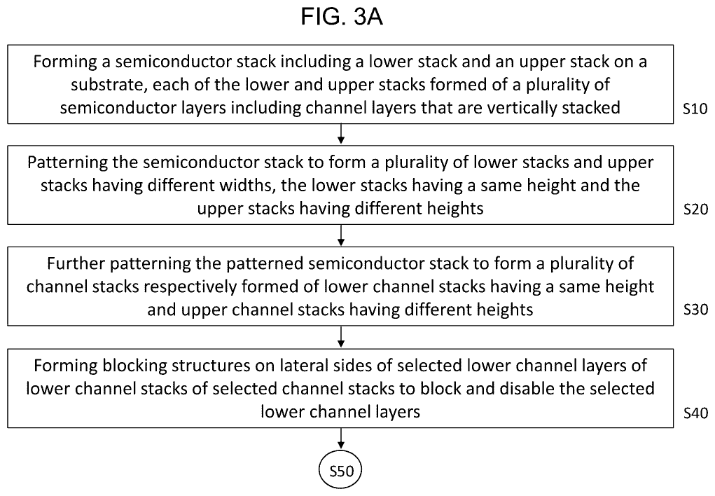

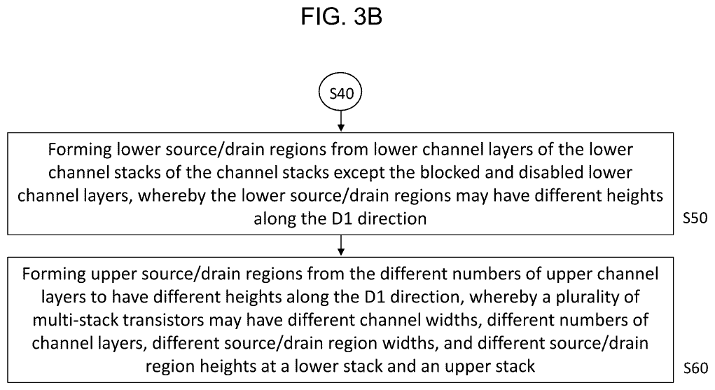

FIGS. 3A and 3B illustrate a flowchart of a method of manufacturing a semiconductor device including a plurality of multi-stack transistors having different channel structures based on blocking structures and additional patterning of active patterns, according to one or more embodiments.

The semiconductor device manufactured according to the flowchart of FIGS. 3A and 3B may be the same as or correspond to the semiconductor device 10 shown in FIGS. 1A-1E and operations performed for each step of manufacturing the semiconductor device may be the same as or similar to those described above in reference to FIGS. 2A-2J. Thus, duplicate descriptions may be omitted herein.

In step S10, a semiconductor stack including a lower stack and an upper stack may be formed on a substrate. Each of the lower stack and the upper stack may be formed of a plurality of semiconductor layers including a plurality of channel layers that are vertically stacked.

In step S20, the semiconductor stack may be patterned to form a plurality of lower stacks and a plurality of upper stacks having different widths, the plurality of lower stacks having a same height and the plurality of upper stacks having different heights.

The semiconductor stack may be patterned in the D1 and D2 directions such that the plurality of lower stacks connected in the D1 direction have smaller widths than the plurality of upper stacks also connected in the D1 direction and formed on the plurality of lower stacks, respectively, the plurality of lower stacks has different widths, and the plurality of upper stacks has different widths. The semiconductor stack may also be patterned in the D3 direction such that the plurality of upper stacks has smaller widths than the plurality of lower stacks, respectively, and further, the plurality of upper stacks has different numbers of upper channel layers while the plurality of lower stacks has a same number of lower channel layers.

In step S30, the patterned semiconductor stack may be further patterned to form a plurality of channel stacks respectively formed of a plurality of lower channel stacks having a same height and a plurality of upper channel stacks respectively formed on the plurality of lower channel stacks and having different heights. The plurality of channel stacks may be defined by a plurality of dummy gate structures formed thereon and openings formed between the plurality of channel stacks by the further patterning of the patterned semiconductor stack.

In step S40, blocking structures may be formed on lateral sides of selected lower channel layers of lower channel stacks of selected channel stacks among the plurality of channel stacks to block and disable the selected lower channel layers. The blocking structures may be formed on the substrate in the openings exposing the selected lower channel layers. Due to the formation of the blocking structures, the plurality of channel stacks may have different numbers of effective lower channel layers.

In step S50, lower source/drain regions may be formed from lower channel layers of the lower channel stacks of the plurality of channel stacks except the blocked and disabled lower channel layers, whereby the lower source/drain regions may have different heights along the D1 direction.

In step S60, upper source/drain regions may be formed from the different numbers of upper channel layers to have different heights along the D1 direction, whereby a plurality of multi-stack transistors may have different channel widths, different numbers of channel layers, different source/drain region widths, and different source/drain region heights at a lower stack and an upper stack.

In the above embodiments described in reference to FIGS. 1A-1E, 2A-2J and 3A-3B, a semiconductor device is structured to include a plurality of multi-stack transistors in which upper FETs may have different numbers of effective upper channel layers by patterning upper active patterns to have different heights (e.g., the steps as shown in FIGS. 2B-2C), while lower FETs may have different numbers of effective lower channel layers by forming blocking structures to block and disable selected lower channel layers (e.g., the step as shown in FIG. 2G). However, the disclosure is not limited thereto, and the number of effective upper channel layers for the upper FETs may be controlled in a different manner as described in the following embodiments.

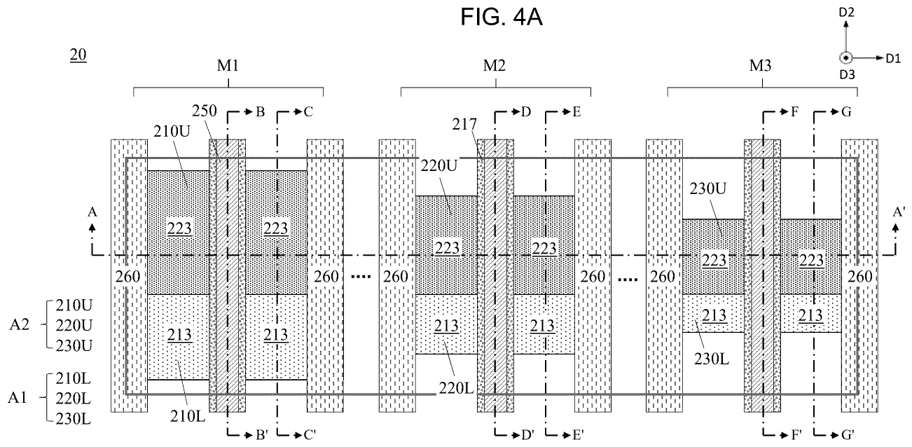

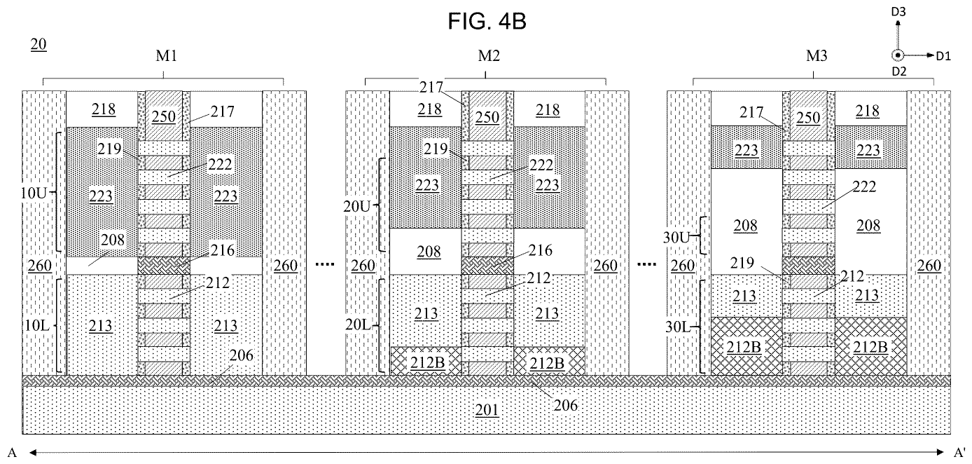

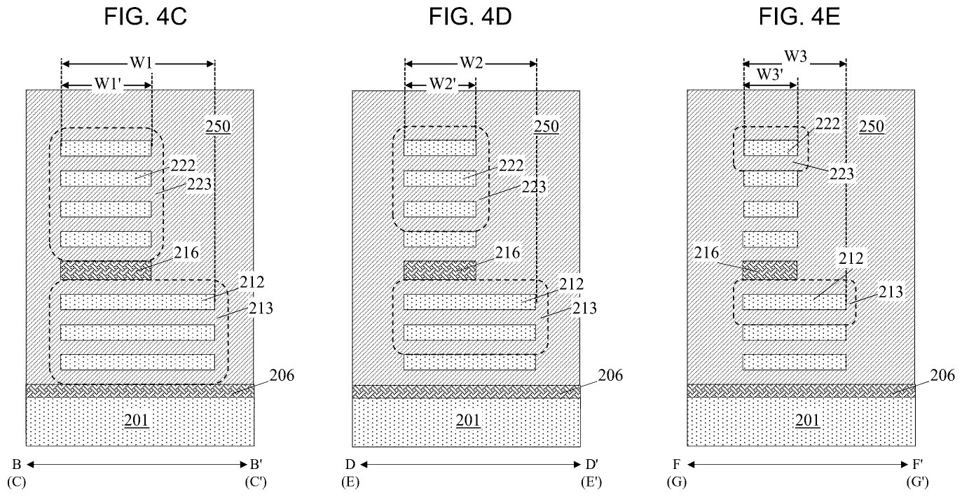

FIGS. 4A-4E illustrate a semiconductor cell in which a semiconductor device including a plurality of multi-stack transistors is formed, the multi-stack transistors having different channel structures based on blocking structures and different structures of interlayer isolation layers, according to one or more other embodiments.

FIG. 4A is a plan view of a semiconductor device 20 formed in a semiconductor cell, FIGS. 4B-4E are a cross-section views of the semiconductor device 20 taken along lines A, A′, B-B′, D-D′, E-E′ and F-F′, respectively, shown in FIG. 4A.

It is to be understood that FIGS. 4A-4E show only selected elements formed on a front side of the semiconductor device 20 such as FEOL structures including channel structures, source/drain regions and gate structures, and thus, some structural elements such as BEOL structures and MOL structures are not shown for brevity purposes. It is also to be understood that FIGS. 4C-4E show, in dashed lines, source/drain regions seen in cross-section views of the semiconductor device 20 taken along lines C-C′, E-E′ and G-G′, respectively, to assist understanding of structural and positional relationships between the source/drain regions, gate structures and SDB structures.

Referring to FIGS. 4A-4E, the semiconductor device 20, similar to the semiconductor device 10 of FIGS. 1A-1E, may include 1^{st} to 3^{rd} multi-stack transistors M1-M3 formed based on a lower active pattern A1 and an upper active pattern A2 which respectively are formed of 1^{st} to 3^{rd} lower active patterns 210L-230L and 1^{st} to 3^{rd} upper active patterns 210U-230U. Further, the 1^{st} to 3^{rd} multi-stack transistors M1-M3 may be respectively formed of a 1^{st} lower FET 10L and a 1^{st} upper FET 10U, a 1^{nd} lower FET 20L and a 1^{nd} upper FET 20U, and a 3^{rd} lower FET 30L and a 3^{rd} upper FET 30U.

Further, each of the 1^{st} to 3^{rd} lower FETs 10L-30L in the semiconductor device 20 may also be formed of lower channel layers 212 and lower source/drain regions 213 on a substrate 201 with a BDI layer 206 therebetween, and a gate structure 250. In addition, each of the 1^{st} to 3^{rd} upper FETs 10U-30U in the semiconductor device 20 may be formed of upper channel layers 222, upper source/drain regions 223 and the gate structure 250. An MDI layer 216 may be formed between the lower channel layers 212 and the upper channel layers 222. The semiconductor device 20 may also include gate spacers 217, inner spacers 219, a lower interlayer isolation layer 208, an upper interlayer isolation layer 218, SDB structures 260, and blocking structures 212B which are the same as or similar to the corresponding structural elements included in the semiconductor device 10. Materials forming the above-described structural elements of the semiconductor device 20 may also be the same as or similar to those forming the corresponding structural elements of the semiconductor device 10. Thus, duplicate descriptions thereof may be omitted herein.

Moreover, width differences between the channel layers 212 and 222 and between source/drain regions 213 and 223 across the 1^{st} to 3^{rd} multi-stack transistors M1-M3 of the semiconductor device 20 may be the same as or similar to those of the semiconductor device 10. For example, the channel layers 212 and 222 of the semiconductor device 20 may have respectively different widths W1, W1′, W2, W2′, W3 and W3′ as the channel layers 112 and 122 of the semiconductor device 10. Thus, duplicate descriptions about the width differences in the semiconductor device 20 may also be omitted herein.

However, the numbers of channel layers in the 1^{st} to 3^{rd} multi-stack transistors M1-M3 of the semiconductor device 20 may be different from those in the 1^{st} to 3^{rd} multi-stack transistors M1-M3 of the semiconductor device 10.

For example, unlike the 1^{st} to 3^{rd} upper FETs 10U-30U of the semiconductor device 10 having different numbers of the upper channel layers 122, the 1^{st} to 3^{rd} upper FETS 10U-30U of the semiconductor device 20 may each have the same number of upper channel layers 222, for example, four, as shown in FIGS. 4B-4E.

However, the numbers of effective upper channel layers of the 1^{st} to 3^{rd} upper FETS 10U-30U of the semiconductor device 20 may be the same as those of the semiconductor device 10. For example, in the semiconductor device 20, the 1^{nd} upper FET 20U may have three effective upper channel layers 222 and one disabled upper channel layer 222, and the 3^{rd} upper FET 30U may have one effective upper channel layer 222 and three disabled upper channel layers 222 while the upper channel layers 222 of 1^{st} upper FET 10U may be all effective.

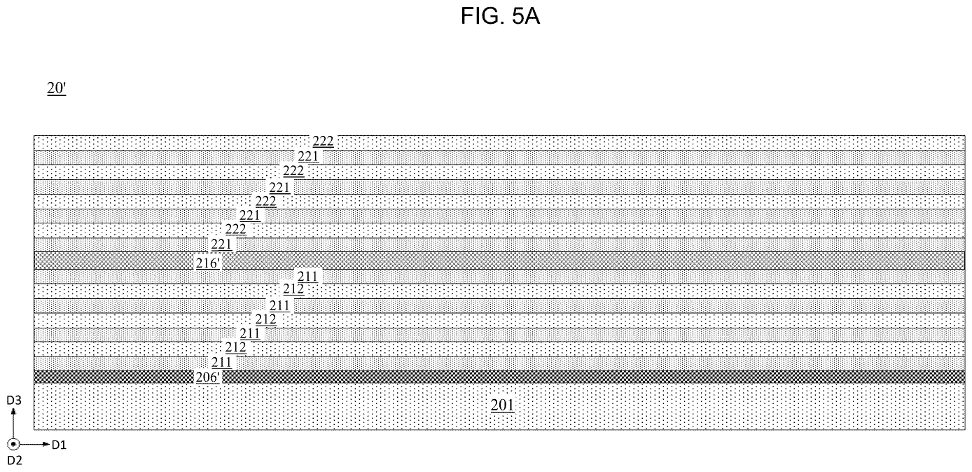

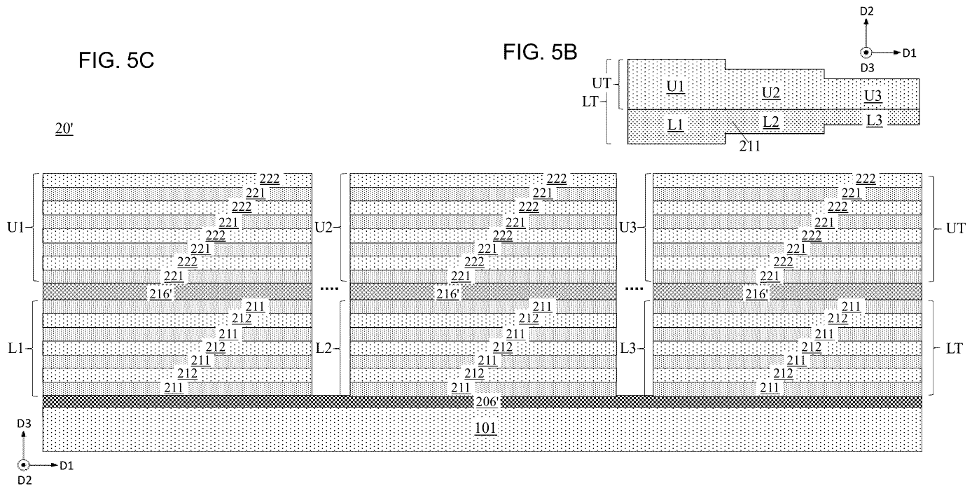

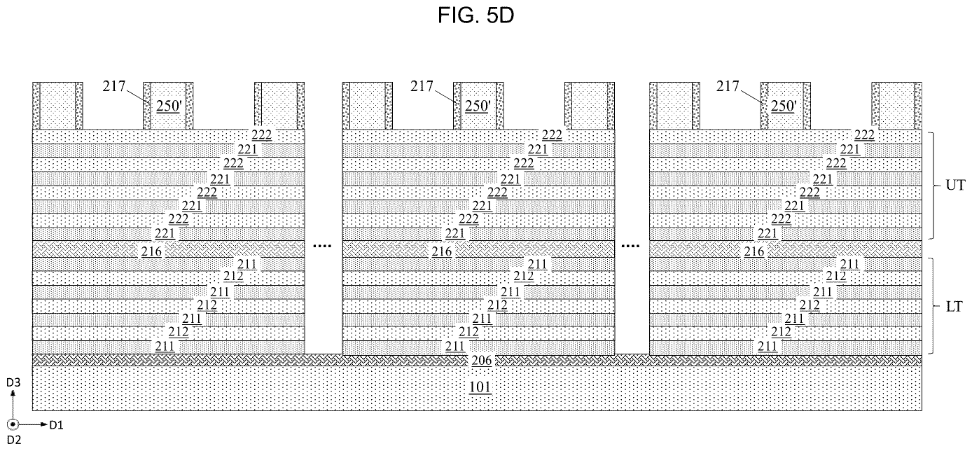

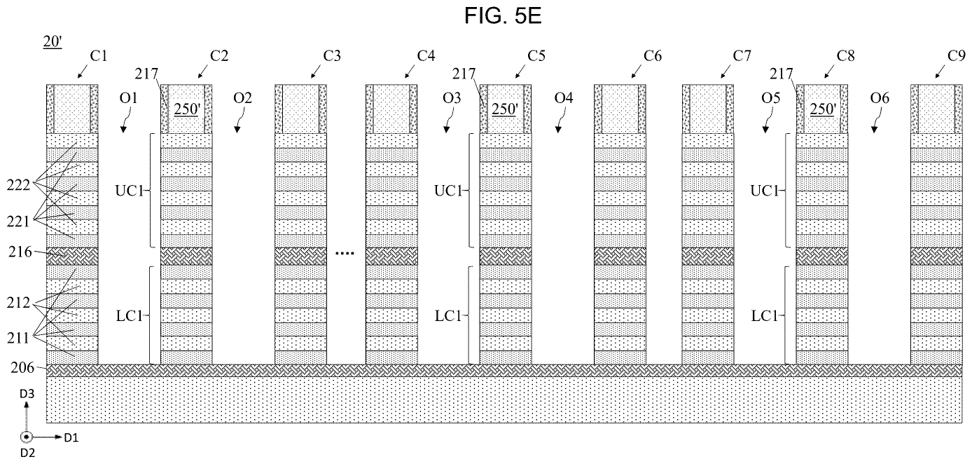

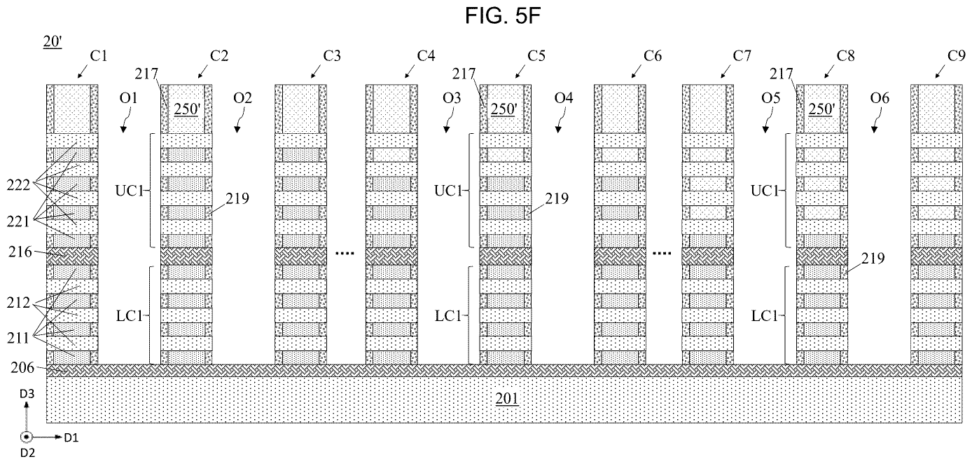

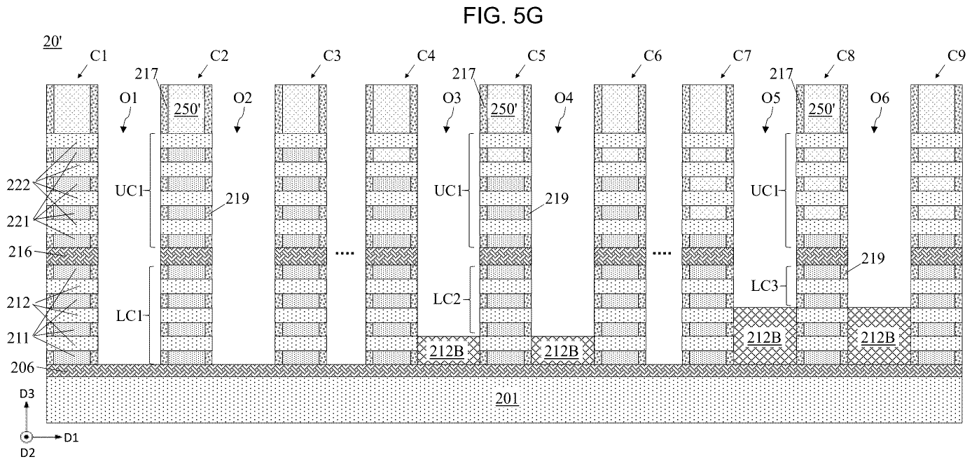

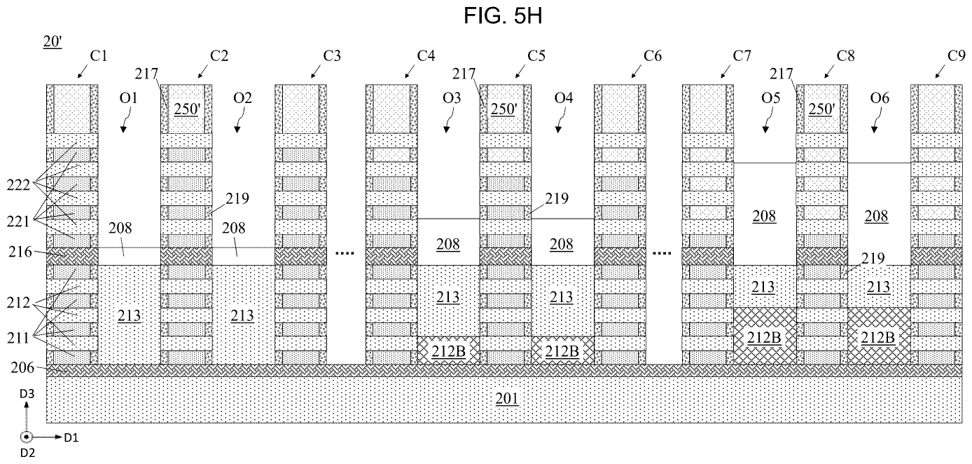

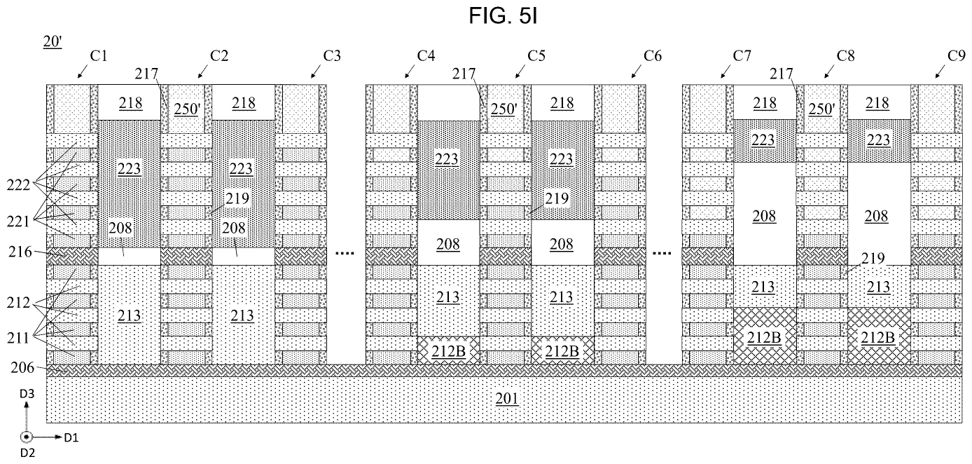

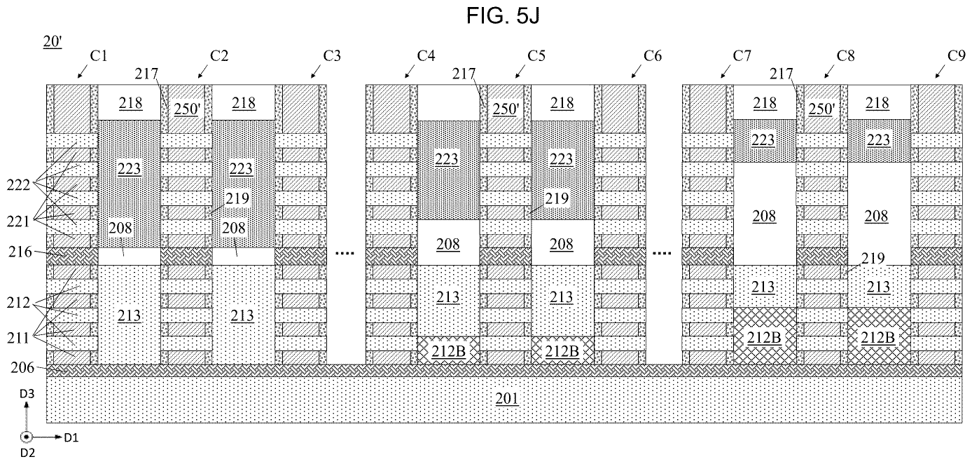

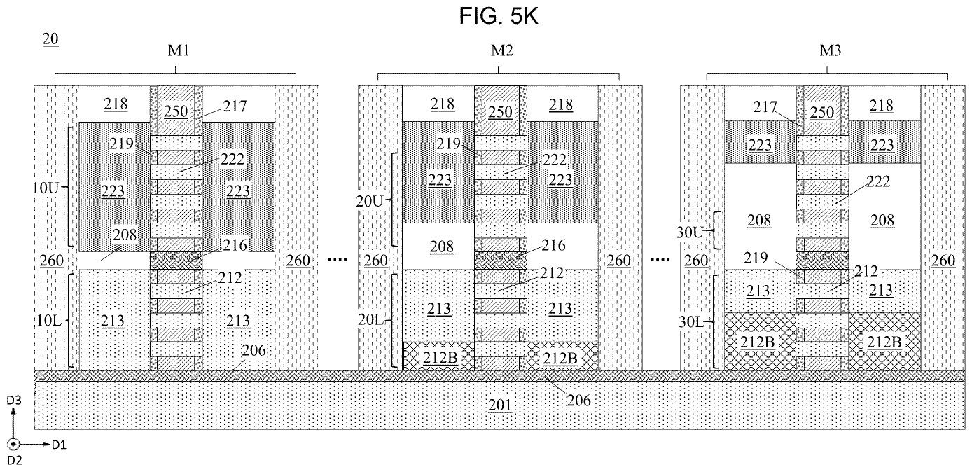

However, while the different numbers of effective upper channel layers 122 in the semiconductor device 10 are achieved by patterning of the 1^{st} to 3^{rd} upper active patterns 110U-130U in the D3 direction as described above in reference to FIGS. 2B-2C, the different numbers of effective upper channel layers 222 in the semiconductor device 20 may be achieved by thickness control of the lower interlayer isolation layer 208 to be further described in reference to FIG. 5H.

As shown in FIG. 4B, the lower interlayer isolation layer 208 in the 2^{nd} multi-stack transistor M2 may be formed to block the lowermost upper channel layer 222, thereby disabling this lowermost upper channel layer 222, and further, preventing epitaxial growth of the upper source/drain regions 223 from the lowermost upper channel layer 222. Further, the lower interlayer isolation layer 208 in the 3^{rd} multi-stack transistor M3 may be formed to block three upper channel layers 222 except the uppermost upper channel layer 222, thereby disabling these three upper channel layer 222, and further, preventing epitaxial growth of the upper source/drain regions 223 from these three upper channel layers 222. In contrast, the lower interlayer isolation layer 208 in the 1^{st} multi-stack transistor M1 is formed to not block any of the upper channel layers 222. Thus, the numbers of the upper channel layers 222 in the semiconductor device 20 may be controlled by how to form the lower interlayer isolation layer 208 on the lower source/drain regions 213 in a process of manufacturing the semiconductor device 20.

The numbers of the lower channel layers 212 across the 1^{st} to 3^{rd} lower FETs 10L-30L of the semiconductor device 20 may be controlled in the same manner as in the semiconductor device 10. For example, in the 1^{nd} lower FET 20L, the blocking structures 212B may be formed between the lower source/drain regions 213 and BDI layer 206, at lateral sides of the lowermost lower channel layer 212 to block and disable the lowermost lower channel layer 212. As another example, in the 3^{rd} lower FET 30L, the blocking structures 212B may be formed between the lower source/drain regions 213 and BDI layer 206, at lateral sides of the two three lower channel layers 212 other than the uppermost lower channel layer 21 to block and disable the three lower channel layers 212.

Thus, the semiconductor device 20 may also implement a plurality of multi-stack transistors having different numbers of channel layers and channel-structure heights in addition to different channel widths in a single-height semiconductor cell to achieve different devices having different device performances.

Herebelow, a method of manufacturing the semiconductor device 20 of FIGS. 4A-4E is provided.

FIGS. 5A-5K illustrate cross-section views of intermediate semiconductor devices after respective steps of manufacturing a semiconductor device including a plurality of multi-stack transistors having different channel structures based on blocking structures and different structures of interlayer isolation layers, according to one or more embodiments.

The semiconductor device manufactured through the steps described in reference to FIGS. 5A-5K may be the same as or correspond to the semiconductor device 20 shown in FIGS. 4A-4E. Thus, materials, functions, and structural characteristics of the intermediate semiconductor devices shown in FIGS. 5A-5K may be the same as or similar to those of the semiconductor device 10 of FIGS. 4A-4E, and thus, duplicate descriptions may be omitted herein while the same reference characters or numerals used in reference to FIGS. 4A-4E may be used herebelow. It is also to be understood here that the cross-section views of FIGS. 5A-5K correspond to the cross-section view of the semiconductor device 20 in the D1 direction as shown in FIG. 4B.

Referring to FIG. 5A, an intermediate semiconductor device 20′ may be formed by epitaxially growing a plurality of semiconductor layers one by one from a substrate 201.

Like the intermediate semiconductor device 10′ shown in FIG. 2A, the intermediate semiconductor device 20′, which is a semiconductor stack, may also be formed through a method such as ultra-high vacuum chemical vacuum chemical deposition, not being limited thereto, to grow, from the substrate 201, a plurality of semiconductor layers. These semiconductor layers may include a bottom sacrificial layer 206′ on the substrate 201, a lower stack formed of lower sacrificial layers 211 and lower channel layers 212 vertically stacked in an alternating manner, a middle sacrificial layer 216′, and an upper stack formed of upper sacrificial layers 221 and upper channel layers 222 vertically stacked in an alternating manner.

The same or similar methods and materials used for the formation of the intermediate semiconductor device 10′in FIG. 2A may be used to form the above-described structural elements of the intermediate semiconductor device 20′, and thus, duplicate descriptions thereof may be omitted herein.

Referring to FIGS. 5B and 5C, the intermediate semiconductor device 10′ obtained in the previous step may be patterned to form a plurality of semiconductor stacks.

By the patterning operation in this step, the intermediate semiconductor device 20′ shown in FIG. 5A may be patterned to form a lower stack LT including 1^{st} to 3^{rd} lower stacks L1-L3 and an upper stack UT including 1^{st} to 3^{rd} upper stacks U1-U3 respectively formed on the 1^{st} to 3^{rd} lower stacks L1-L3.

Like the intermediate semiconductor device 10′ shown in FIGS. 2B and 2C, the intermediate semiconductor device 20′ may be patterned in the D1 direction and the D2 direction as shown in FIG. 5B such that the 2^{nd} lower stack L2 and the 2^{nd} upper stack U2 have smaller widths than the 1^{st} lower stack L1 and the 1^{st} upper stack U1, respectively, and the 3^{rd} lower stack L3 and the 3^{rd} upper stack U3 have smaller widths than the 1^{nd} lower stack L2 and the 1^{nd} upper stack U2, respectively.

However, unlike in the intermediate semiconductor device 10′ shown in FIGS. 2B and 2C, a D3-direction patterning may be performed only to partially expose a top surface of the uppermost lower sacrificial layer 211, which is a top surface of the lower stack LT formed of the 1^{st} to 3^{rd} lower stacks L1-L3, while the 1^{st} to 3^{rd} lower stacks L1-L3 have a same height and the 1^{st} to 3^{rd} upper stacks U1-U3 may also have a same height which is greater than the height of the 1^{st} to 3^{rd} lower stacks L1-L3. Thus, the 1^{st} to 3^{rd} upper stacks U 1-U3 may have smaller widths than the 1^{st} to 3^{rd} lower stacks L1-L3, respectively.

The foregoing D3-direction patterning may be performed by partially removing respective portions of the upper channel layers 222, the upper sacrificial layers 221 and the middle sacrificial layer 216′ to expose a portion of the uppermost lower sacrificial layer 211 forming top surfaces of the 1^{st} to 3^{rd} lower stacks L1-L3 at a same level as shown in FIG. 5B.

The patterning operations in this step may be performed through, for example, hard masking, lithography and dry etching.

Referring to FIG. 5D, the bottom sacrificial layer 206′ and the middle sacrificial layer 216′ may be removed and replaced by a BDI layer 206 and an MDI layer 216, respectively, and a plurality of dummy gate structures 250′ and gate spacers 217 may be formed at a predetermined interval on the intermediate semiconductor device 20′.

The removal of the bottom sacrificial layer 206′ and the middle sacrificial layer 216′, the formation of the BDI layer 206 and the MDI layer 216, and the formation of the dummy gate structure 250′ with the gate spacers 217 in the intermediate semiconductor device 20′ may be performed in the same manner as in the semiconductor device 10′ as described in reference to FIG. 2D. Thus, duplicate descriptions thereof may be omitted herein.

However, due to the different D3-direction patterning of the intermediate semiconductor device 20′ in the step of FIGS. 5B and 5C, the dummy gate structures 250′ of the intermediate semiconductor device 20′ may have a same height while the dummy gate structures 150′ of the intermediate semiconductor device 10′ have different heights along the lower stack LT and the upper stack UT in the D1 direction.

Referring to FIG. 5E, the intermediate semiconductor device 20′ may be patterned based on the dummy gate structure 250′ and the gate spacers 217 to form 1^{st} to 7^{th} channel stacks C1-C7 with respective openings O1-O6 therebetween on the substrate 201.

The intermediate semiconductor device 20′ obtained in the previous step may be patterned to form the 1^{st} to 9^{th} channel stacks C1-C9 in the same manner as those of the intermediate semiconductor device 10′ as described in reference to FIG. 2E, and thus, duplicate descriptions thereof may be omitted herein.

However, due to the different D3-direction patterning of the intermediate semiconductor device 20′ in the step of FIGS. 5B and 5C, an upper channel stack UC1 of each of the 1^{st} to 3^{rd} channel stacks C1-C3, an upper channel stack UC2 of each of the 4^{th} to 6^{th} channel stacks C4-C6, and an upper channel stack UC3 of each of the 7^{th} to 9^{th} channel stacks C7-C9 may all have a same number of upper sacrificial layers and a same number of upper channel layers, for example, four upper sacrificial layers 221 and four upper channel layers 222.

Still, a lower channel stack LC1 of each of the 1^{st} to 3^{rd} channel stacks C1-C3, a lower channel stack LC2 of each of the 4^{th} to 6^{th} channel stacks C4-C6, and a lower channel stack LC3 of each of the 7^{th} to 9^{th} channel stacks C7-C9 may all have a same number of lower sacrificial layers and a same number of lower channel layers, for example, four lower sacrificial layers 211 and three lower channel layers 212.

Referring to FIG. 5F, side portions of each of the sacrificial layers 211 and 221 in each of the channel stacks C1-C7 may be removed, and inner spacers 219 may be formed in spaces provided by the removal of the side portions of each of the sacrificial layers 211 and 221.

The formation of the inner spacers 219 on side surfaces of the sacrificial layers 211 and 221 in the intermediate semiconductor device 20′ may be performed in the same manner as the formation of the inner spacers 119 on side surfaces of the sacrificial layers 111 and 121 in the intermediate semiconductor device 10′ as described in reference to FIG. 2F. Thus, duplicate descriptions thereof may be omitted herein.

Referring to FIG. 5G, blocking structures 212B may be formed to isolate or block selected channel layers in the intermediate semiconductor device 10′.

The formation of the blocking structures 212B in the openings O3 and O4 at lateral sides of the 5^{th} channel structure C5 and the openings O5 and O6 at lateral sides of the 8^{th} channel stack C8 on the top surface of the BDI layer 206 may be performed in the same manner as the formation of the blocking structures 112B in the intermediate semiconductor device 10′ as described in reference to FIG. 2G. Thus, duplicate descriptions thereof may be omitted herein

Due to the blocking structures 212B, the lowermost lower channel layer 212 of each of the 4^{th} to 6^{th} channel stacks C4-C6 and two lowermost lower channel layers 212 of each of the 7^{th} to 9^{th} channel stacks C7-C9 may be blocked and disabled toward the openings O3-O6. Thus, a multi-stack transistor to include a channel structure to be formed from the 4^{th} to 6^{th} channel stacks C4-C6 may have only two effective lower channel layers 212 in the 5^{th} channel stack, and a multi-stack transistor to include a channel structure to be formed from the 7^{th} to 9^{th} channel stacks C7-C9 may have only one effective lower channel layer 212 in the 8^{th} channel stack C8.

Referring to FIG. 5H, lower source/drain regions 213 may be formed in the openings O1-O6 and lower interlayer isolation layer 208 may be formed on the lower source/drain regions 213 to block selected channel layers.

The formation of the lower source/drain regions 213 may be performed in the same manner as the formation of the lower source/drain regions 113 in the intermediate semiconductor device 10′, and thus, duplicate descriptions thereof may be omitted herein.

However, the lower interlayer isolation layer 208 may be formed in a manner different from the lower interlayer isolation layer 108 which may be formed only at lateral sides of the middle isolation layer 116 in the openings O1-O6 on the 1^{st} source/drain regions 113 in the intermediate semiconductor device 10′. In the openings O1 and O2, the lower interlayer isolation layer 208 may be formed only at lateral sides of the middle isolation layer. In the other openings, however, the lower interlayer isolation layer 208 may be formed to be thicker than in the openings O1 and O2.

For example, in the openings O3 and O4, the lower interlayer isolation layer 208 may be formed at lateral sides of the middle isolation layer 216, the lowermost inner spacers 219 above the middle isolation layer 208, and the lowermost upper channel layers 222. Thus, the lower interlayer isolation layer 208 in the openings O3 an O4 may block and disable the lowermost upper channel layers 222 while the remaining upper channel layers 222 are exposed through the openings O3 and O4.

As another example, in the opening O5 and O6, the lower interlayer isolation layer 208 may be formed at lateral sides of the middle isolation layer 216, three lowermost inner spacers 219 above the middle isolation layer 208, and three lowermost upper channel layers 222. Thus, the lower interlayer isolation layer 208 in the openings O5 and O6 may block and disable the three lowermost upper channel layers 222 while the remaining uppermost upper channel layer 222 is exposed through the openings O5 and O6.

The lower interlayer isolation layer 208 may be formed of a low-k dielectric material such as silicon oxide (e.g., SiO₂) as the lower interlayer isolation layer 108 of the intermediate semiconductor device 10′.

Referring to FIG. 5I, upper source/drain regions 223 may be formed on the lower interlayer isolation layer 208 and an upper interlayer isolation layer 218 may be formed on the upper source/drain regions 223.

The formation of the upper source/drain regions 223 may be performed in the same manner as the formation of the upper source/drain regions 123 in the intermediate semiconductor device 10′, and thus, duplicate descriptions thereof may be omitted herein.

However, due to the height or thickness differences of the lower interlayer isolation layer 208 in the openings O1-O6 as described above, the upper source/drain regions 223 may also have different thicknesses in the openings O1-O6.

For example, while the upper source/drain regions 223 may be formed in the opening O1 and O2 from four upper channel layers 222 exposed therethrough like the upper source/drain regions 123 of the intermediate semiconductor device 10′, the upper source/drain regions 223 may be formed in the openings O3 and O4 from only three upper channel layers 222 exposed therethrough due to the lower interlayer isolation layer 208 blocking and disabling the lowermost upper channel layer 222. As another example, the upper source/drain regions 223 may be formed in the openings O5 and O6 from only the uppermost upper channel layer 222 exposed therethrough due to the upper interlayer isolation layer 218 blocking and disabling the three other upper channel layers 222. Thus, the upper source/drain regions 223 may have different heights in the openings O1-O6.

In the meantime, due to the above-described channel-width differences and channel-number differences, widths and heights of the source/drain regions 213 and 223 grown from the respective channel layers may also differ in a plurality of multi-stack transistors to be formed therefrom.

Subsequent to the formation of the upper source/drain regions 223, the upper interlayer isolation layer 218 may be formed on the upper source/drain regions 223. The upper interlayer isolation layer 218 may also be formed of a low-k dielectric material such as silicon oxide (e.g., SiO₂) as the interlayer isolation layer 108.

Referring to FIG. 5J, the dummy gate structures 250′ and the sacrificial layers 211 and 221 may be removed and replaced by respective gate structures 250.

The removal of the dummy gate structures 250′ and the sacrificial layers 211 and 221 and the formation of the gate structures 250 may be performed in the same manner as the removal of the dummy gate structures 150′ and the sacrificial layers 111 and 121 and the formation of the gate structures 150 in the intermediate semiconductor device 10′, and thus, duplicate descriptions thereof may be omitted herein.

Referring to FIG. 5K, the 1^{st}, 3^{rd}, 4^{th}, 6^{th}, 7^{th} and 9^{th} channel stacks C1, C3, C4, C6, C7 and C9 may be removed and replaced by respective SDB structures 260 to form a semiconductor device 20 including multi-stack transistors M1-M3 isolated by the SDB structures 260.

The formation of the SDB structures 260 may be performed in the same manner as the formation of the SDB structures 160 in the intermediate semiconductor device 10′, and thus, duplicate descriptions thereof may be omitted herein.

Through the above embodiments described in reference to FIGS. 5A-5K, a semiconductor device including a plurality of multi-stack transistors having different channel widths, different numbers of channel layers, different source/drain region widths, and different source/drain region heights at a lower stack and an upper stack may be formed on a same substrate and implemented in a semiconductor cell having a predetermined cell height.

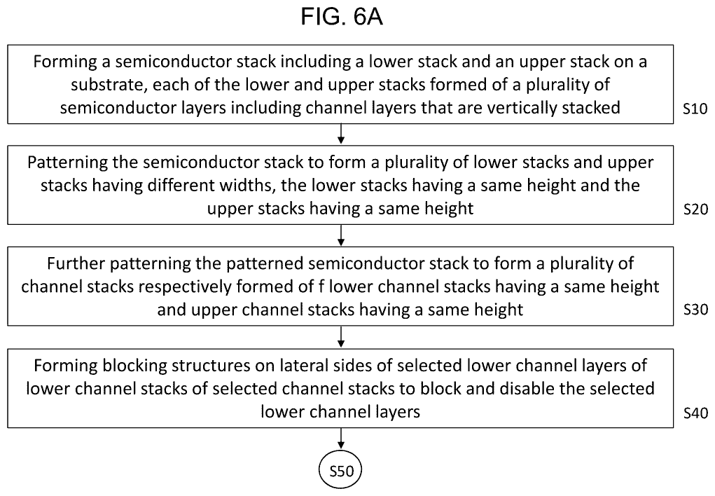

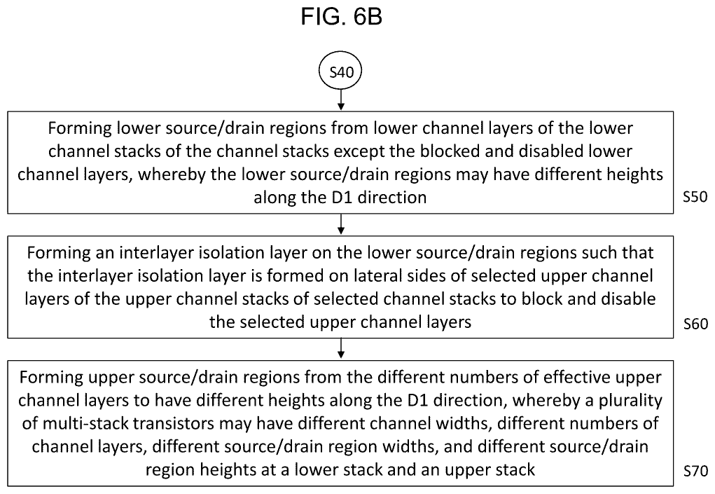

FIGS. 6A and 6B illustrate a flowchart of a method of manufacturing a semiconductor device including a plurality of multi-stack transistors having different channel structures based on blocking structures and different structures of interlayer isolation layers, according to one or more embodiments.

The semiconductor device manufactured according to the flowchart of FIGS. 6A and 6B may be the same as or correspond to the semiconductor device 10 shown in FIGS. 4A-4E and operations performed for each step of manufacturing the semiconductor device may be the same as or similar to those described above in reference to FIGS. 5A-5K. Thus, duplicate descriptions may be omitted herein.

In step S10, a semiconductor stack including a lower stack and an upper stack may be formed on a substrate. Each of the lower stack and the upper stack may be formed of a plurality of semiconductor layers including a plurality of channel layers that are vertically stacked.

In step S20, the semiconductor stack may be patterned to form a plurality of lower stacks and a plurality of upper stacks having different widths, the plurality of lower stacks having a same height and the plurality of upper stacks having a same height which is greater than the height of the plurality of lower stacks.

The semiconductor stack may be patterned in the D1 and D2 directions such that the semiconductor stack formed of the plurality of lower stacks and the plurality of upper stacks have different widths along the D1 direction. Further, the semiconductor stack may also be patterned in the D3 direction such that the plurality of upper stacks has smaller widths than the plurality of lower stacks while the plurality of lower stacks have a same height and the plurality of upper stacks have a same height which is greater than the height of the plurality of lower stacks.

In step S30, the patterned semiconductor stack may be further patterned to form a plurality of channel stacks respectively formed on a plurality of lower channel stacks having a same height and a plurality of upper channel stacks respectively formed thereon and having a same height. The plurality of channel stacks may be defined by a plurality of dummy gate structures formed thereon and openings formed between the plurality of channel stacks by the further patterning of the patterned semiconductor stack.

In step S40, blocking structures may be formed on lateral sides of selected lower channel layers of lower channel stacks of selected channel stacks among the plurality of channel stacks to block and disable the selected lower channel layers. The blocking structures may be formed on the substrate in the openings exposing the selected lower channel layers. Due to the formation of the blocking structures, the plurality of channel stacks may have different numbers of effective lower channel layers.

In step S50, lower source/drain regions may be formed from lower channel layers of the lower channel stacks of the plurality of channel stacks except the blocked and disabled lower channel layers, whereby the lower source/drain regions may have different heights along the D1 direction.

In step S60, an interlayer isolation layer may be formed on the lower source/drain regions such that the interlayer isolation layer is formed on lateral sides of selected upper channel layers of the upper channel stacks of selected channel stacks among the plurality of channel stacks to block and disable the selected upper channel layers. Due to the formation of the interlayer isolation layer in the foregoing manner, the plurality of channel stacks may have different numbers of effective upper channel layers.

In step S70, upper source/drain regions may be formed from the different numbers of effective upper channel layers to have different heights along the D1 direction, whereby a plurality of multi-stack transistors may have different channel widths, different numbers of channel layers, different source/drain region widths, and different source/drain region heights at a lower stack and an upper stack.

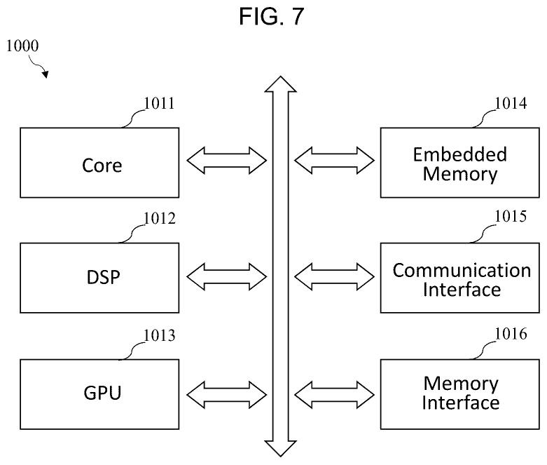

FIG. 7 is a schematic block diagram illustrating an electronic device including one or more semiconductor devices in which a plurality of multi-stack transistors are formed to have different channel widths, different numbers of channel layers, different source/drain region widths, and different source/drain region heights at a lower stack and an upper stack, according to one or more embodiments. These semiconductor devices may include the semiconductor device 10 shown in FIGS. 1A-1E or the semiconductor device 20 shown in FIGS. 4A-4E.

Referring to FIG. 7, an SoC 1000 may be an integrated circuit in which components of a computing system or other electronic systems are integrated. As an example of the SoC 1000, an application processor (AP) may include at least one processor and components for various functions. The SoC 1000 may include a core 1011 (e.g., a processor), a digital signal processor (DSP) 1012, a graphic processing unit (GPU) 1013, an embedded memory 1014, a communication interface 1015, and a memory interface 1016. The components of the SoC 1000 may communicate with each other through a bus 1007.

The core 1011 may process instructions and control operations of the components included in the SoC 1000. For example, the core 1011 may process a series of instructions to run an operating system and execute applications on the operating system. The DSP 1012 may generate useful data by processing digital signals (e.g., a digital signal provided from the communication interface 1015). The GPU 1013 may generate data for an image output by a display device from image data provided from the embedded memory 1014 or the memory interface 1016, or may encode the image data.

The embedded memory 1014 may store data necessary for the core 1011, the DSP 1012, and the GPU 1013 to operate. The communication interface 1015 may provide an interface for a communication network or one-to-one communication. The memory interface 1016 may provide an interface for an external memory of the SoC 1000, such as a dynamic random access memory (DRAM), a flash memory, etc.

At least one of the core 1011, the DSP 1012, the GPU 1013, and/or the embedded memory 1014 may include the semiconductor device 10 or 20 shown in FIGS. 1A-1E and 4A-4E.

The foregoing is illustrative of example embodiments and is not to be construed as limiting the disclosure. Although a few example embodiments have been described, those skilled in the art will readily appreciate that many modifications are possible in the above embodiments without materially departing from the disclosure.

What is claimed is:

1. A semiconductor device comprising:
a 1^{st} multi-stack transistor and a 2^{nd} multi-stack transistor arranged in a 1^{st} direction intersecting a 2^{nd} direction,
wherein the 1^{st} multi-stack transistor comprises a 1^{st} lower transistor and a 1^{st} upper transistor above the 1^{st} lower transistor in a 3^{rd} direction that intersects the 1^{st} direction and the 2^{nd} direction,
wherein the 2^{nd} multi-stack transistor structure comprises a 2^{nd} lower transistor and a 2^{nd} upper transistor above the 2^{nd} lower transistor in the 3^{rd} direction, and
wherein the 1^{st} lower transistor and the 2^{nd} lower transistor have different numbers of effective lower channel layers.

2. The semiconductor device of claim 1, wherein the 1^{st} lower transistor and the 2^{nd} lower transistor have a same number of lower channel layers comprising respective effective lower channel layers.

3. The semiconductor device of claim 2, wherein the 1^{st} lower transistor or the 2^{nd} lower transistor has at least one disabled lower channel layer.

4. The semiconductor device of claim 3, wherein the 1^{st} lower transistor or the 2^{nd} lower transistor has at least two lower channel layers arranged in the 3^{rd} direction, and
wherein the at least one disabled lower channel layer comprises the lowermost lower channel layer among the at least two lower channel layers.

5. The semiconductor device of claim 4, further comprising a blocking structure between the disabled lower channel layer and a source/drain region of the 1^{st} lower transistor or the 2^{nd} lower transistor,
wherein the blocking structure comprises an insulation material.

6. The semiconductor device of claim 1, wherein the 1^{st} upper transistor and the 2^{nd} upper transistor have different numbers of effective upper channel layers.

7. The semiconductor device of claim 6, wherein the 1^{st} upper transistor and the 2^{nd} upper transistor have a same number of upper channel layers comprising respective effective upper channel layers.

8. The semiconductor device of claim 7, wherein the 1^{st} upper transistor or the 2^{nd} upper transistor has at least one disabled upper channel layer.

9. The semiconductor device of claim 8, wherein the 1^{st} upper transistor or the 2^{nd} upper transistor has at least two upper channel layers arranged in the 3^{rd} direction, and
wherein the at least one disabled upper channel layer comprises the lowermost upper channel layer among the at least two upper channel layers.

10. The semiconductor device of claim 9, further comprising an interlayer isolation layer between the at least one disabled upper channel layer and a source/drain region of the 1^{st} upper transistor or the 2^{nd} upper transistor,
wherein the interlayer isolation layer comprises an insulation material.

11. The semiconductor device of claim 1, wherein the 1^{st} lower transistor and the 2^{nd} lower transistor have different lower-channel widths in the 2^{nd} direction.

12. A semiconductor device comprising:
a 1^{st} multi-stack transistor and a 2^{nd} multi-stack transistor arranged in a 1^{st} direction intersecting a 2^{nd} direction,
wherein the 1^{st} multi-stack transistor comprises a 1^{st} lower transistor and a 1^{st} upper transistor above the 1^{st} lower transistor in a 3^{rd} direction that intersects the 1^{st} direction and the 2^{nd} direction,
wherein the 2^{nd} multi-stack transistor structure comprises a 2^{nd} lower transistor and a 2^{nd} upper transistor above the 2^{nd} lower transistor in the 3^{rd} direction, and
wherein the 1^{st} upper transistor and the 2^{nd} upper transistor have different numbers of effective upper channel layers.

13. The semiconductor device of claim 12, wherein the 1^{st} upper transistor and the 2^{nd} upper transistor have a same number of upper channel layers comprising respective effective upper channel layers.

14. The semiconductor device of claim 13, wherein the 1^{st} upper transistor or the 2^{nd} upper transistor has at least one disabled upper channel layer.

15. The semiconductor device of claim 14, wherein the 1^{st} upper transistor or the 2^{nd} upper transistor has at least two upper channel layers arranged in the 3^{rd} direction, and
wherein the at least one disabled upper channel layer comprises the lowermost upper channel layer among the at least two upper channel layers.

16. The semiconductor device of claim 15, further comprising an interlayer isolation layer between the at least one disabled upper channel layer and a source/drain region of the 1^{st} upper transistor or the 2^{nd} upper transistor,
wherein the interlayer isolation layer comprises an insulation material.

17. A semiconductor device comprising:
a 1^{st} transistor comprising a plurality of channel layers and a 1^{st} source/drain region at a lateral side of the plurality of channel layers,
wherein at least one of the plurality of channel layers is not connected to the 1^{st} source/drain region.

18. The semiconductor device of claim 17, further comprising a blocking structure comprising an insulation material,
wherein the at least one of the plurality of channel layers is connected to the blocking structure.

19. The semiconductor device of claim 18, wherein the blocking structure is between a substrate, on which the plurality of channel layers is formed, and the 1^{st} source/drain region in a vertical direction.

20. The semiconductor device of claim 17, further comprising:
a 2^{nd} transistor at a lateral side of the 1^{st} transistor, the 2^{nd} transistor comprising a 2^{nd} source/drain region,
wherein all of channel layers of the 2^{nd} transistor are connected to the 2^{nd} source/drain regions.

21. A method of manufacturing a semiconductor device, the method comprising forming a 1^{st} multi-stack transistor and a 2^{nd} multi-stack transistor such that:
the 1^{st} multi-stack transistor and the 2^{nd} multi-stack transistor are arranged in a 1^{st} direction intersecting a 2^{nd} direction;
the 1^{st} multi-stack transistor comprises a 1^{st} lower transistor and a 1^{st} upper transistor above the 1^{st} lower transistor in a 3^{rd} direction that intersects the 1^{st} direction and the 2^{nd} direction;
the 2^{nd} multi-stack transistor structure comprises a 2^{nd} lower transistor and a 2^{nd} upper transistor above the 2^{nd} lower transistor in the 3^{rd} direction; and
the 1^{st} lower transistor and the 2^{nd} lower transistor have different numbers of effective lower channel layers.

22. The method of claim 21, wherein the 1^{st} multi-stack transistor and the 2^{nd} multi-stack transistor are formed such that the 1^{st} lower transistor and the 2^{nd} lower transistor have a same number of lower channel layers comprising respective effective lower channel layers.

23. The method of claim 22, wherein the 1^{st} multi-stack transistor and the 2^{nd} multi-stack transistor are formed such that the 1^{st} lower transistor or the 2^{nd} lower transistor has at least one disabled lower channel layer.

24. The method of claim 23, wherein the 1^{st} multi-stack transistor and the 2^{nd} multi-stack transistor are formed such that:
the 1^{st} lower transistor or the 2^{nd} lower transistor has at least two lower channel layers arranged in the 3^{rd} direction; and
the at least one disabled lower channel layer comprises the lowermost lower channel layer among the at least two lower channel layers.

25. The method of claim 24, wherein the 1^{st} multi-stack transistor and the 2^{nd} multi-stack transistor are formed such that a blocking structure comprising an insulation material is formed between the disabled lower channel layer and a source/drain region of the 1^{st} lower transistor or the 2^{nd} lower transistor.

26. The method of claim 21, wherein the 1^{st} multi-stack transistor and the 2^{nd} multi-stack transistor are formed such that the 1^{st} upper transistor and the 2^{nd} upper transistor have different numbers of effective upper channel layers.

27. The method of claim 26, wherein the 1^{st} multi-stack transistor and the 2^{nd} multi-stack transistor are formed such that the 1^{st} upper transistor and the 2^{nd} upper transistor have a same number of upper channel layers comprising respective effective upper channel layers.

28. The method of claim 27, wherein the 1^{st} multi-stack transistor and the 2^{nd} multi-stack transistor are formed such that the 1^{st} upper transistor or the 2^{nd} upper transistor has at least one disabled upper channel layer.

29. The method of claim 28, wherein the 1^{st} multi-stack transistor and the 2^{nd} multi-stack transistor are formed such that:
the 1^{st} upper transistor or the 2^{nd} upper transistor has at least two upper channel layers arranged in the 3^{rd} direction, and
the at least one disabled upper channel layer comprises the lowermost upper channel layer among the at least two upper channel layers.

30. The semiconductor device of claim 29, wherein the 1^{st} multi-stack transistor and the 2^{nd} multi-stack transistor are formed such that an interlayer isolation layer comprising insulation material is formed between the at least one disabled upper channel layer and a source/drain region of the 1^{st} upper transistor or the 2^{nd} upper transistor.
